(19) United States
(12) Patent Application Publication
(10) Pub. No.: US 2003/0054287 A1
(43) Pub. Date: Mar. 20, 2003

(54) Resist composition

(75) Inventors: Shoichiro Yasunami, Shizuoka (JP); Fumiyuki Nishiyama, Shizuoka (JP); Makoto Momota, Shizuoka (JP); Koichi Kawamura, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/120,551

(22) Filed: Apr. 12, 2002

(30) Foreign Application Priority Data
Apr. 13, 2001 (JP) P.2001-115596
Jun. 5, 2001 (JP) P.2001-169770
Aug. 24, 2001 (JP) P.2001-254879

(51) Int. Cl. G03F 7/004

(52) U.S. Cl. 430/270.1; 430/914

(57) ABSTRACT

A resist composition containing a compound generating an acid by irradiation of an active ray or radiation and having a sulfonimide structure represented by formula (I) defined in the specification, which is excellent in sensitivity, resolution, pattern profile and edge roughness.

### FIELD OF THE INVENTION

The present invention relates to a resist composition suitably used in an ultra-microlithography process, for example, the production of VLSI and high capacity microtips, and other photofabrication processes. More particularly, it relates to a positive resist composition and a negative resist composition capable of forming high precision patterns using a radiation, e.g., an electron beam, an X ray or an excimer laser.

### BACKGROUND OF THE INVENTION

The electron beam lithography is regarded as the next generation pattern formation technique or the pattern formation technique after the next generation and the development of a positive resist having high sensitivity, high resolution and a rectangular profile forming property has been strongly desired.

According to the electron beam lithography, accelerated electron beams collide with atoms constituting a resist material and scatter to supply energy to compounds and as a result, the reaction of resist material occurs, whereby an image is formed. To use highly accelerated electron beams increases the rectilinear propagation of electron beams and decreases the influence of electron scattering so that it makes possible the formation of pattern having high resolution, rectangular profile and excellent edge roughness. On the other hand, however, the transmittance of electron beam increases, resulting in decrease in sensitivity. Thus, a trade off relation between the sensitivity and the resolution, resist profile and edge roughness exists in the electron beam lithography, and it is a problem to be solved to fulfill requirements for both the sensitivity and the resolution, resist profile and edge roughness.

With respect to the positive resist for electron beam or X ray, resist techniques for KrF excimer laser have been mainly diverted and investigated. For instance, a combination of a compound capable of generating an acid upon electron beam irradiation and an amine compound having a boiling point of not more than 250° C. as described in JP-A-2000-181065 (the term “JP-A” as used herein means an “unexamined published Japanese patent application”), a combination of a polymer having an acid decomposable group, an acid generator and an electron beam sensitizer as described in European Patent 919, 867, and a combination of amide compounds as described in JP—W-7-508840 (the term “JP-W” as used herein means an “unexamined published international patent application”) are known. Further, a maleimide compound as described in JP-A-3-200968, a sulfonamide compound as described in JP-A-7-92680, and a sulfonamide compound containing a partial structure of —SO₂—NH—SO₂— as described in JP-A-11-44950 are known. However, these attempts do not solve the problem to fulfill requirements for both the high sensitivity and the high resolution, good rectangular resist profile and excellent edge roughness. The term “edge roughness” used herein means a phenomenon wherein an edge between a line pattern of resist and a surface of substrate irregularly fluctuates in the direction vertical to the line due to the characteristics of resist. When the pattern is observed from just above, the edge is uneven. Since the unevenness is transferred to the substrate in an etching step, the large unevenness causes a defect in electric properties thereby resulting in yield reduction. The edge roughness is also referred to as “line edge roughness” hereinafter.

Therefore, it is difficult to fulfill requirements for both the sufficiently high sensitivity and the high resolution, good resist profile and excellent edge roughness in hitherto known techniques and it has been desired to solve the problem.

Also, in lithography using an excimer laser beam having a short wavelength, for example, KrF or ArF, as an exposure light source, a target is to form an ultra fine pattern having not more than 0.20 μm. However, various resist properties including the sensitivity, resolution pattern profile and edge roughness are not fulfilled at the same time similar to the case of electron beam lithography, and it has been strongly desired to provide a resist composition satisfying these properties at the same time.

On the other hand, in processes for the production of semiconductor devices, for example, IC or LSI, fine fabrication is also conducted by means of lithography using a negative resist composition. In recent years, as the degree of integration increases in integrated circuits, it has been desired to form an ultra fine pattern in the submicron region or the quarter micron region. With such a trend, an exposure wavelength tends to become shorter such as from g-line to i-line or a KrF excimer laser beam. Further, the development of lithography using an electron beam also proceeds at present. As a resist suitable for the excimer laser or electron beam lithography, a chemically amplified resist is widely employed.

The chemically amplified resist is a material wherein an acid is generated in the exposed area upon the irradiation of a deep ultraviolet ray or an electron beam and solubility in a developer between the exposed area and the unexposed area is differentiated by a reaction using the acid as a catalyst, whereby a pattern is formed on a substrate. The chemically amplified resist has advantages in that it has high sensitivity and high resolution and is capable of forming a pattern using a compound (hereinafter, also referred to as an “acid generator”) that generates an acid by a small amount of the irradiation.

Although the chemically amplified resist is advantageous in view of the high sensitivity and high resolution as described above, line edge roughness of pattern has become an unignorably large problem in the chemically amplified resist with the continuous trend of miniaturization in pattern. Especially, in an ultra fine region of not more than 0.25 μm, the line edge roughness is an extremely important problem to be solved. The trade off relation between high sensitivity and high resolution and good line edge roughness also exists herein, and it is important to fulfill the requirements for both the sensitivity, resolution and line edge roughness.

In the field of chemically amplified negative resists, various investigations have been made from the standpoint of acid generators and crosslinking agents. For instance, a triazine photo-acid generator as described in JP-A-7-128855, a photo-acid generator that generates a carboxylic acid as described in JP-A-9-43837 and JP-A-11-125907, a methoxymethylmelamine crosslinking agent as described in JP-A-5-181277 and JP-A-7-146556, and an alkoxymethyl ether crosslinking agent as described in JP-A-6-83055 are known. With respect to additives, a carboxylic acid imide compound is described in JP-A-6-214391.

However, any of these attempts do not fulfill requirements in the ultra fine region for the high sensitivity, high resolution, good pattern profile and excellent edge roughness at the same time.

### SUMMARY OF THE INVENTION

Therefore, an object of the present invention is to solve the problems of performance-improving techniques in the ultra fine processing of semiconductor devices using an active ray or radiation, particularly, an electron beam, an X ray, a KrF excimer laser beam or an ArF excimer laser beam.

Another object of the present invention is to provide a positive or negative resist composition excellent in sensitivity and resolution.

A further object of the present invention is to provide a positive or negative resist composition which fulfills requirements for rectangular pattern profile and excellent line edge roughness at the same time in addition to the sensitivity and resolution.

Other objects of the present invention will become apparent from the following description.

As a result of the intensive investigations, it has been found that the above-described objects can be accomplished by a resist composition comprising a compound having a specific sulfonimide structure to complete the present invention.

Specifically, it has been found that the above-described objects can be accomplished by a positive resist composition comprising a polymer having an acid-decomposable group and the compound having a specific sulfonimide structure to complete the present invention.

It has also be found that the above-described objects can be accomplished by a chemically amplified negative resist composition comprising an alkali-soluble polymer, a crosslinking agent and the compound having a specific sulfonimide structure to complete the present invention.

Specifically, the present invention includes the following resist compositions:

(1) A resist composition comprising (C) a compound having a sulfonimide suructure represented by the following formula (I):

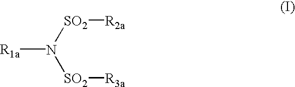

wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or a heterocyclic group which may have a substituent.

(2) A positive resist composition comprising (B) a polymer which is insoluble or hardly soluble in an aqueous alkali solution but becomes soluble in the aqueous alkali solution by the action of an acid, and (C) a compound having a sulfonimide structure represented by the following formula (I):

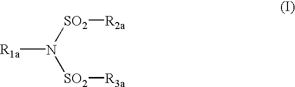

wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or a heterocyclic group which may have a substituent.

(3) The positive resist composition as described in (2) further comprising (A) a compound which generates an acid by irradiation of an active ray or radiation other than the compound (C).

(4) The positive resist composition as described in (2) or (3) further comprising (E) a nitrogen-containing basic compound.

(5) The positive resist composition as described in any one of (2) to (4), wherein the active ray or radiation is an electron beam or an X ray.

(6) The positive resist composition as described in any one of (2) to (4), wherein the active ray or radiation is an excimer laser beam having a wavelength of from 150 to 250 nm.

(7) A negative resist composition comprising (F) an alkali-soluble polymer, (G) a crosslinking agent crosslinking with the alkali-soluble polymer (F) by the action of an acid, and (C) a compound having a sulfonimide structure represented by the following formula (I):

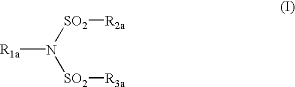

wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or a heterocyclic group which may have a substituent.

(8) The negative resist composition as described in (7) further comprising (H) a compound which generates an acid by irradiation of an active ray or radiation other than the compound (C).

(9) The negative resist composition as described in (7) or (8) further comprising (E) a nitrogen-containing basic compound.

(10) The negative resist composition as described in any one of (7) to (9), wherein the alkali-soluble polymer (F) is a polymer containing a repeating unit represented by the following formula (b):

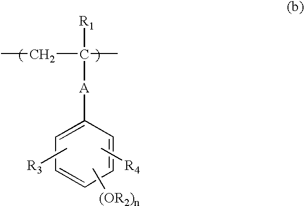

wherein R₁ represents a hydrogen atom, a halogen atom, a cyano group or an alkyl group which may have a substituent; R₂ represents a hydrogen atom, an alkyl group which may have a substituent, a cycloalkyl group which may have a substituent, an aryl group which may have a substituent, an aralkyl group which may have a substituent or an acyl group which may have a substituent; R₃ and R₄, which may be the same or different, each represent a hydrogen atom, a halogen atom, a cyano group, an alkyl group which may have a substituent, a cycloalkyl group which may have a substituent, an alkenyl group which may have a substituent, an aralkyl group which may have a substituent or an aryl group which may have a substituent; A represents a single bond, an alkylene group which may have a substituent, an alkenylene group which may have a substituent, a cycloalkylene group which may have a substituent, an arylene group which may have a substituent, —O—, —SO₂—, —O—CO—R₅—, —CO—O—R₆— or —CO—N(R₇)—R₈—; R₅, R₆ and R₈, which may be the same or different, each represent a single bond, an alkylene group which may have a substituent, an alkenylene group which may have a substituent, a cycloalkylene group which may have a substituent, an arylene group which may have a substituent, or a divalent group formed by combining the above-described alkylene, alkenylene, cycloalkylene or arylene group with at least one member selected from an ether structure, an ester structure, an amide structure, a urethane structure and a ureido structure; R₇ represents a hydrogen atom, an alkyl group which may have a substituent, a cycloalkyl group which may have a substituent, an aralkyl group which may have a substituent or an aryl group which may have a substituent; and n represents an integer of from 1 to 3; or plural R₂'s, or R₂ and R₃ or R₄ may combine with each other to form a ring.

(11) The negative resist composition as described in any one of (7) to (9), wherein the alkali-soluble polymer (F) is a polymer containing at least one repeating unit selected from those represented by the following formulae (b-2) and (b-3):

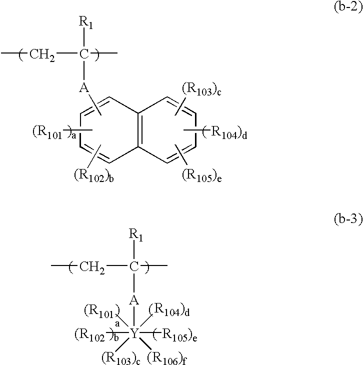

wherein R₁ represents a hydrogen atom, a halogen atom, a cyano group or an alkyl group which may have a substituent; A represents a single bond, an alkylene group which may have a substituent, an alkenylene group which may have a substituent, a cycloalkylene group which may have a substituent, an arylene group which may have a substituent, —O—, —SO₂—, —O—CO—R₅—, —CO—O—R₆— or —CO—N(R₇)—R₈—; R₅, R₆ and R₈, which may be the same or different, each represent a single bond, an alkylene group which may have a substituent, an alkenylene group which may have a substituent, a cycloalkylene group which may have a substituent, an arylene group which may have a substituent, or a divalent group formed by combining the above-described alkylene, alkenylene, cycloalkylene or arylene group with at least one member selected from an ether structure, an ester structure, an amide structure, a urethane structure and a ureido structure; R₇ represents a hydrogen atom, an alkyl group which may have a substituent, a cycloalkyl group which may have a substituent, an aralkyl group which may have a substituent or an aryl group which may have a substituent; R₁₀₁ to R₁₀₆ each independently represent a hydroxy group, a carboxy group, an amino group, an alkyl group which may have a substituent, a cycloalkyl group which may have a substituent, an alkoxy group which may have a substituent, an alkylcarbonyloxy group which may have a substituent, an alkylsulfonyloxy group which may have a substituent, an alkenyl group which may have a substituent, an aryl group which may have a substituent, an aralkyl group which may have a substituent, an N-alkylamino group which may have a substituent or an N-dialkylamino group which may have a substituent; a to f each independently represent an integer of from 0 to 3; and Y represents a condensed polycyclic aromatic structure selected from those shown below.

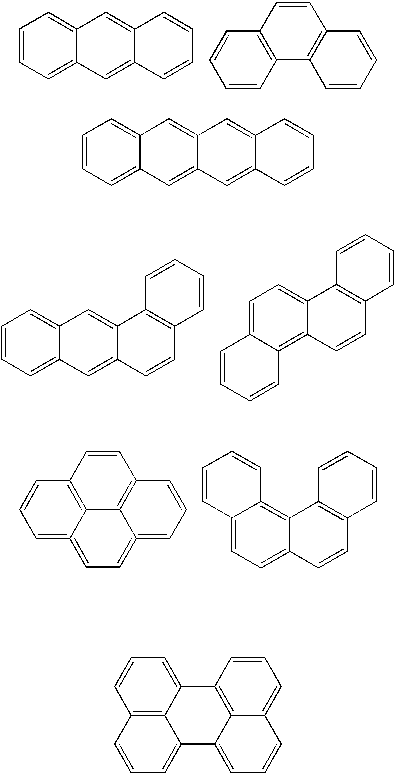

(12) The negative resist composition as described in any one of (7) to (11), wherein the active ray or radiation is an excimer laser beam having a wavelength of from 150 to 250 nm, an electron beam or an X ray.

### DETAILED DESCRIPTION OF THE INVENTION

The compound of component (C) having a sulfonimide structure represented by formula (I) for use in the resist composition according to the present invention is described in detail below.

The compound of component (C) is a compound that generates an acid by irradiation of an actinic ray or radiation.

In formula (I), R₁ₐ, R₂ₐ and R₃ₐ, which may be the same or different, each represent an alkyl group (preferably having from 1 to 20 carbon atoms), a cycloalkyl group (preferably having from 4 to 18 carbon atoms), an aryl group (preferably having from 6 to 20 carbon atoms), an aralkyl group (preferably having from 7 to 20 carbon atoms) or a heterocyclic group (preferably having from 4 to 10 carbon atoms). The heterocyclic group is preferably an aromatic group containing a hetero atom and more preferably an aromatic group containing a hetero atom and having from 4 to 10 carbon atoms.

Each of the alkyl group, cycloalkyl group, aryl group, aralkyl group and heterocyclic group may have a substituent. Examples of the substituent include an alkyl group having from 1 to 4 carbon atoms, an alkoxy group having from 1 to 4 carbon atoms, a halogen atom (e.g., fluorine, chlorine or iodine), an alkyl group having from 1 to 4 carbon atoms substituted with a halogen atom, an aryl group having from 6 to 10 carbon atoms, an alkenyl group having from 2 to 6 carbon atoms, a cyano group, a hydroxy group, a carboxy group, an alkoxycarbonyl group having from 2 to 5 carbon atoms, an alkylcarbonyloxy group having from 2 to 5 carbon atoms and a nitro group.

R₁ₐ, R₂ₐ and R₃ₐ each preferably represent an alkyl group having from 1 to 16 carbon atoms, which may have a substituent, a cycloalkyl group having from 4 to 15 carbon atoms, which may have a substituent, an aryl group having from 6 to 18 carbon atoms, which may have a substituent, an aralkyl group having from 7 to 15 carbon atoms, which may have a substituent or an aromatic group having from 4 to 6 carbon atoms and containing a hetero atom, which may have a substituent, and more preferably an alkyl group having from 1 to 12 carbon atoms, which may have a substituent, a cycloalkyl group having from 5 to 12 carbon atoms, which may have a substituent (e.g., cyclohexyl or cyclooctyl), an aryl group having from 6 to 15 carbon atoms, which may have a substituent, an aralkyl group having from 7 to 15 carbon atoms, which may have a substituent or an aromatic group having from 4 to 6 carbon atoms and containing a hetero atom, which may have a substituent.

Preferred examples of R₁ₐ include an alkyl group having from 1 to 6 carbon atoms, which may have a substituent (e.g., methyl, ethyl, n-propyl, tert-butyl or n-hexyl), a cycloalkyl group having from 6 to 12 carbon atoms, which may have a substituent (e.g., cyclohexyl or cyclooctyl), an aryl group having from 6 to 10 carbon atoms, which may have a substituent (e.g., phenyl, naphthyl or p-tolyl) and an aromatic group having from 4 to 6 carbon atoms and containing a hetero atom (e.g., nitrogen or sulfur), which may have a substituent (e.g., 2-pyridyl, 3-pyridyl, 4-pyridyl or 2-thienyl). Preferred examples of R₂ₐ or R₃ₐ include an alkyl group having from 1 to 12 carbon atoms, which may have a substituent (e.g., methyl, ethyl, n-butyl, n-octyl, n-dodecyl, trifluoromethyl, nonafluorobutyl or perfluorooctyl), an aryl group having from 6 to 10 carbon atoms, which may have a substituent (e.g., phenyl, naphthyl, a fluorine-substituted phenyl group, a trifluoromethyl-stituted phenyl group or an alkoxyphenyl group) and an aralkyl group having from 7 to 15 carbon atoms, which may have a substituent (e.g., benzyl or phenethyl).

Particularly preferred groups for R₁ₐ, R₂ₐ and R₃ₐ include an alkyl group having from 1 to 4 carbon atoms, which may have a substituent (e.g., methyl, ethyl, n-propyl, n-butyl or tert-butyl), an aryl group having from 6 to 14 carbon atoms, which may have a substituent (e.g., phenyl, naphthyl or anthryl), an aralkyl group having from 7 to 12 carbon atoms, which may have a substituent (e.g., benzyl or phenethyl) and an aromatic group having from 5 to 6 carbon atoms and containing a hetero atom, which may have a substituent (e.g., 2-pyridyl, 3-pyridyl, 4-pyridyl or 2-thienyl).

Specific examples of the compound of component (C) having a sulfonimide structure in the molecule thereof are set forth below, but the present invention should not be construed as being limited thereto.

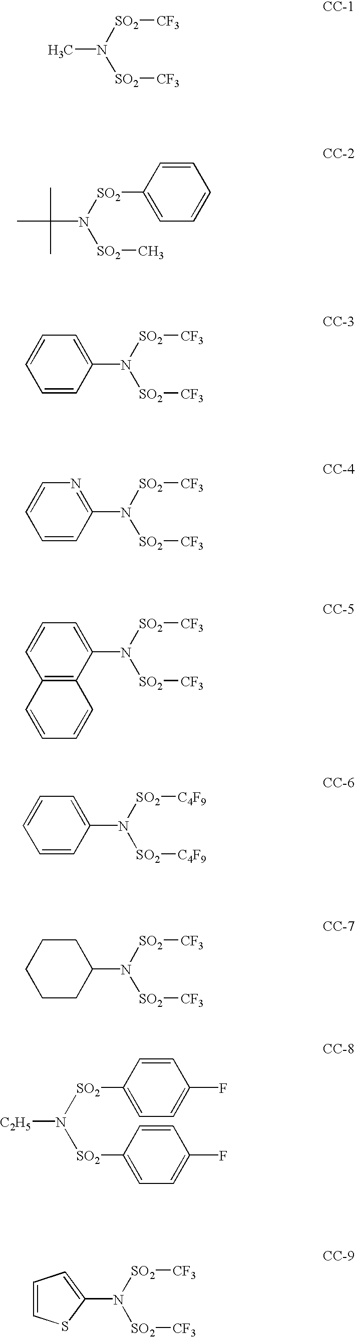

The amount of the compound of component (C) used in the resist composition is suitably from 0.01 to 20% by weight, preferably from 0.02 to 15% by weight, and more preferably from 0.03 to 10% by weight, based on the solid content of the resist composition. The compounds of component (C) may be used individually or in a mixture of two or more thereof.

The positive resist composition according to the present invention is described in detail below.

The positive resist composition of the present invention contains a polymer (component (B)), which is insoluble or hardly soluble in an aqueous alkali solution but becomes soluble in the aqueous alkali solution by the action of an acid in addition to the compound of component (C).

The polymer of component (B) includes a resin having a group decomposable with an acid in the main chain or side chain thereof, or in both the main chain and side chain thereof. A resin having a group decomposable with an acid in its side chain is more preferred.

Preferred examples of the group decomposable with an acid include a group represented by —COOA⁰ and a group represented by —O—B⁰. Examples of a group containing such a group include a group represented by —R⁰—COOA⁰ and a group represented by —Ar—O—B⁰.

In the above formulae, A⁰ represents —C(R⁰¹)(R⁰²)(R⁰³), —Si(R⁰¹) (R⁰²)(R⁰³) or —C(R⁰⁴)(R⁰⁵)—O—R⁰⁶, B⁰ represents —A⁰ or —CO—O—A⁰, R⁰ represents a single bond or an alkylene group having from 1 to 6 carbon atoms. R⁰ preferably represents a single bond or an alkylene group having from 1 to 4 carbon atoms, and particularly preferably a single bond or an alkylene group having from 1 to 2 carbon atoms. R⁰¹, R⁰² and R⁰³ each independently represent an alkyl group having from 1 to 8 carbon atoms, a cycloalkyl group having from 4 to 10 carbon atoms or an aryl group having from 6 to 15 carbon atoms, or R⁰¹, R⁰² and R⁰³ may be combined with each other to form a ring or bridged ring. R⁰¹, R⁰² and R⁰³ each independently preferably represent an alkyl group having from 1 to 6 carbon atoms, a cycloalkyl group having from 5 to 8 carbon atoms or an aryl group having from 6 to 12 carbon atoms, and particularly preferably an alkyl group having from 1 to 4 carbon atoms, a cyclohexyl group or a phenyl group. R⁰⁴ and R⁰⁵ each independently represent a hydrogen atom or an alkyl group having from 1 to 8 carbon atoms. R⁰⁴ and R⁰⁵ each independently preferably represent a hydrogen atom or an alkyl group having from 1 to 6 carbon atoms, and particularly preferably a hydrogen atom or an alkyl group having from 1 to 4 carbon atoms. R⁰⁶ represents an alkyl group having from 1 to 15 carbon atoms, which may contain an ether bond or a thioether bond, a cycloalkyl group having from 4 to 10 carbon atoms, an aryl group having from 6 to 15 carbon atoms or a combination thereof. R⁰⁶ preferably represents an alkyl group having from 1 to 12 carbon atoms, which may contain an ether bond or a thioether bond, a cycloalkyl group having from 5 to 8 carbon atoms, an aryl group having from 6 to 12 carbon atoms or a combination thereof, and particularly preferably an alkyl group having from 1 to 8 carbon atoms, which may contain an ether bond or a thioether bond, a cyclohexyl group, a phenyl group, a naphthyl group or a combination thereof. It is also preferred that R⁰⁶ is combined with R⁰⁴ or R⁰⁵ to form a ring. Ar represents an arylene group having from 6 to 12 carbon atoms. Ar particularly preferably represents a phenylene group.

Preferred examples of the group decomposable with an acid include a silyl ether group, a cumyl ester group, an acetal group, a tetrahydropyranyl ether group, an enol ether group, an enol ester group, a tertiary alkyl ether group, a tertiary alkyl ester group and a tertiary alkylcarbonate group. More preferred examples thereof include a tertiary alkyl ester group, a tertiary alkylcarbonate group, a cumyl ester group, an acetal group and a tetrahydropyranyl ether group.

In a case wherein the group decomposable with an acid is bonded as a side chain, a parent resin is an alkali-soluble resin having an —OH group or a —COOH group, preferably an —R⁰—COOH group or an —Ar—OH group, in the side chain. Examples of the parent resin include alkali-soluble resins described hereinafter.

An alkali-dissolution rate of the alkali-soluble resin is preferably not less than 170 angstroms/sec, and more preferably not less than 330 angstroms/sec, when measured in 0.261 N tetramethylammonium hydroxide (TMAH) at 23° C.

From these standpoints, particularly referred examples of the alkali-soluble resin include a poly(o-, m-, or p-hydroxystyrene), a copolymer of o-, m-, or p-hydroxystyrene, a hydrogenated poly(hydroxystyrene), a halogen- or alkyl-substituted poly(hydroxystyrene), a partially O-alkylated or O-acylated poly(hydroxystyrene), a styrene-hydroxystyrene copolymer, an α-methylstyrene-hydroxystyrene copolymer and a hydrogenated novolak resin.

The polymer of component (B) for use in the present invention can be obtained by reacting an alkali-soluble resin with a precursor of the group decomposable with an acid, or by copolymerizing a monomer for forming an alkali-soluble resin, which has the group decomposable with an acid, with any of various monomers, as described, for example, in European Patent 254,853, JP-A-2-25850, JP-A-3-223860 and JP-A-4-251259.

Specific examples of the polymer of component (B) for use in the present invention are set forth below, but the present invention should not be construed as being limited thereto.

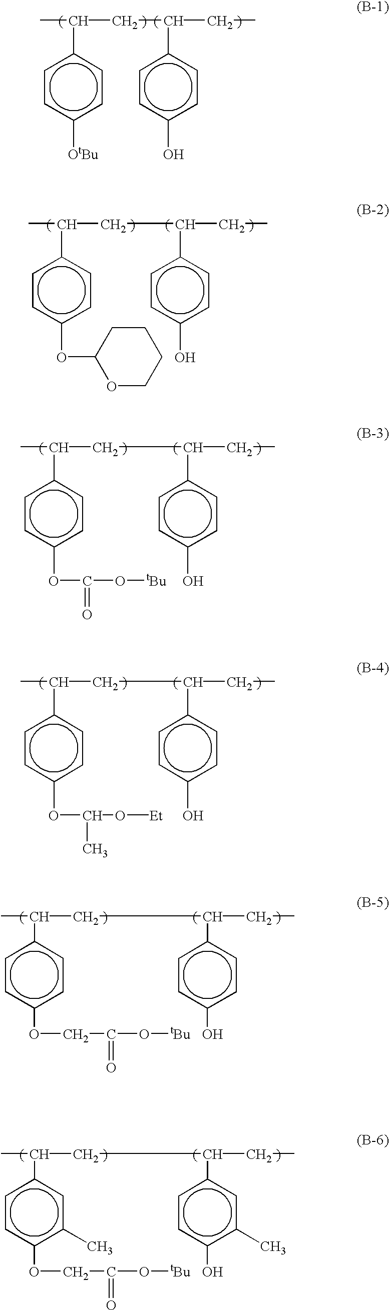

A ratio of content of the group decomposable with an acid in the resin is indicated by a formula of B/(B+S) wherein B represents a number of the group decomposable with an acid and S represents a number of an alkali-soluble group which is not protected by the group decomposable with an acid. The ratio of content is preferably from 0.01 to 0.7, more preferably from 0.05 to 0.50, and still more preferably from 0.05 to 0.40. The ratio of content of more than 0.7 is disadvantageous in view of film shrinking after PEB, adhesion failure to a substrate or occurrence of scamming. On the other hand, the ratio of content of less than 0.01 is also not preferred, since a remarkable standing wave effect on the sidewall of pattern may occur in some cases.

The weight average molecular weight (Mw) of the polymer of component (B) is preferably in a range of from 2,000 to 200,000. If it is less than 2,000, decrease in a film thickness of the unexposed area during development is large and on the other hand, if it exceeds 200,000, a dissolution rate of the alkali-soluble resin per se to alkali decreases, resulting in lowering sensitivity. The weight average molecular weight is more preferably in a range of from 5,000 to 100,000, and still more preferably in a range of from 8,000 to 50,000.

The molecular weight distribution (Mw/Mn) is preferablr from 1.0 to 4.0, more preferably from 1.0 to 2.0, and particularly preferably from 1.0 to 1.6.

The weight average molecular weight is measured by gel permeation chromatography and defined in terms of polystyrene.

Two or more of the polymers of component (B) may be used in the resist composition of the present invention.

The amount of the polymer of component (B) is ordinarily from 80 to 98% by weight, and preferably from 85 to 96% by weight, based on the solid content of the positive resist composition of the present invent1on.

The positive resist composition of the present invention is preferably contain (A) a compound which generates an acid by irradiation of an active ray or radiation other than the compound of component (C) in addition to the compound of component (C). The compound of component (A) is also referred to as a photo-acid generator or an acid generator, hereinafter.

The compound of component (A) used in the present invention includes any compound which generates an acid by irradiation of an active ray or radiation.

Specifically, the compound which generates an acid by irradiation of an active ray or radiation used can be appropriately selected from photoinitiators for photo-cationic polymerization, photoinitiators for photo-radical polymerization, photo-achromatic agents for dyes, photo-discoloring agents, compounds generating an acid with known light used for microresists, and a mixture thereof.

Also, compounds in which a group or compound generating an acid by irradiation of an active ray or radiation is introduced into the main chain or side chain of a polymer, for example, compounds as described, for example, in JP-A-63-26653, JP-A-55-164824, JP-A-62-69263, JP-A-63-146038, JP-A-63-163452, JP-A-62-153853 and JP-A-63-146029 can be used.

Further, compounds generating an acid with light as described, for example, in U.S. Pat. No. 3,779,778 and European Patent 126,712 can be used.

Moreover, known onium salts, for example, diazonium salts, phosphonium salts, iodonium salts, sulfonium salts or selenonium salts, organic halogen compounds, O-nitrobenzylsulfonate compounds, N-iminosulfonate compounds, N-imidosulfonate compounds, diazosulfone compounds, diazodisulfone compounds and disulfone compounds can be used.

Preferred examples of the compound include sulfonate compounds of sulfonium or iodonium, sulfonic acid ester compounds of N-hydroxyimide and disulfonyldiazomethane compounds.

Of these compounds, in particular, N-imidosulfonate compounds as described, for example, in JP-A-10-7653 and JP-A-11-2901, diazodisulfone compounds as described, for example, in JP-A-4-210960 and European Patent 417,557, and sulfonium salts and iodonium salts represented by formulae (I) to (III) shown below are preferred. The sulfonium salts and iodonium salts represented by formulae (I) to (III) are most preferred.

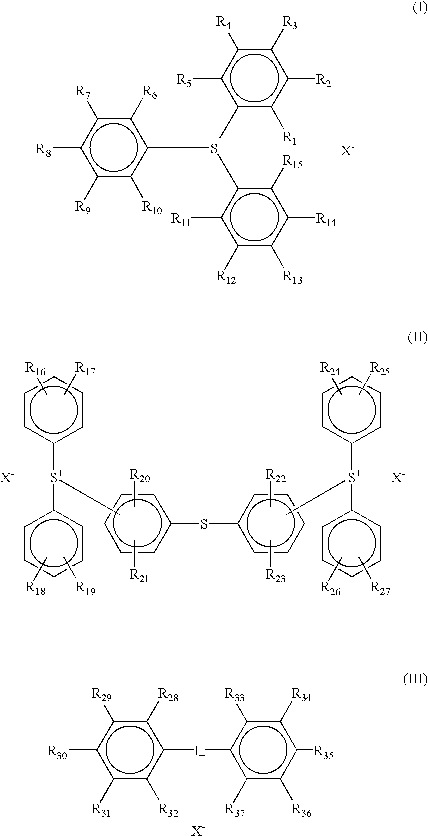

In formulae (I) to (III), R₁ to R₃₇ each independently represent a hydrogen atom, an alkyl group, an alkoxy group, a hydroxy group, a halogen atom or —S—R₃₈.

The alkyl group represented by R₁ to R₃₇ may be a straight chain, branched or cyclic alkyl group. The straight chain or branched alkyl group includes, for example, an alkyl group having from 1 to 4 carbon atoms, e.g., methyl, ethyl, propyl, n-butyl, sec-butyl and tert-butyl groups. The cyclic alkyl group includes, for example, a cyclic alkyl group having from 3 to 8 carbon atoms, e.g., cyclopropyl, cyclopentyl and cyclohexyl groups.

The alkoxy group represented by R₁ to R₃₇ may be a straight chain, branched or cyclic alkoxy group. The straight chain or branched alkoxy group includes an alkoxy group having from 1 to 8 carbon atoms, e.g., methoxy, ethoxy, hydroxyethoxy, propoxy, n-butoxy, isobutoxy, sec-butoxy, tert-butoxy and octyloxy groups. The cyclic alkoxy group includes, for example, cyclopentyloxy and cyclohexyloxy groups.

The halogen atom represented by R₁ to R₃₇ includes fluorine, chlorine, bromine and iodine atoms.

R₃₈ in the —S—R₃₈ represented by R₁ to R₃₇ represents an alkyl group or an aryl group. The alkyl group represented by R₃₈ includes, for example, those described for the alkyl group represented by R₁ to R₃₇.

The aryl group represented by R₃₈ includes an aryl group having from 6 to 14 carbon atoms, e.g., phenyl, tolyl, methoxyphenyl and naphthyl groups.

The alkyl group, alkoxy group and aryl group represented by R₁ to R₃₈ each may further have a substituent. Preferred examples of the substituent include an alkoxy group having from 1 to 4 carbon atoms, an aryl group having from 6 to 10 carbon atoms, an alkenyl group having from 2 to 6 carbon atoms, a cyano group, a hydroxy group, a carboxy group, an alkoxycarbonyl group, a nitro group and a halogen atom (e.g., fluorine, chlorine and iodine atom).

In the groups represented by R₁ to R₁₅ in formula (I), at least two groups thereof may combine with each other to form a ring. The ring may be formed by directly combining the terminals of the groups represented R₁ to R₁₅. Also, the ring may be formed by indirectly combining the groups represented R₁ to R₁₅ through one or more atoms selected from carbon, oxygen, sulfur and nitrogen atoms. The ring structure formed by combining two or more groups represented by R₁ to R₁₅ includes, for example, a furan ring, a dihydrofuran ring, a pyran ring, a trihydropyran ring, a thiophene ring and a pyrrole ring. The same as above can be applied to R₁₆ to R₂₇ in formula (II), and two or more groups represented by R₁₆ to R₂₇ may combine with each other directly or indirectly to form a ring. The same as above can also be applied to R₂₈ to R₃₇ in formula (III).

Each of formulae (I) to (III) has X⁻. The X⁻ of formulae (I) to (III) is an anion of an acid. The acid forming the anion includes preferably benzenesulfonic acid, naphthalenesulfonic acid and anthracenesulfonic acid each having at least one fluorine atom. The benzenesulfonic acid, naphthalenesulfonic acid and anthracenesulfonic acid may be those substituted directly with a fluorine atom or those substituted with a substituent having a fluorine atom. The substituent includes an organic group substituted with a fluorine atom, for example, an alkyl group, an alkoxy group, an acyl group, an acyloxy group, a sulfonyl group, a sulfonyloxy group, a sulfonylamino group, an aryl group, an aralkyl group and an alkoxycarbonyl group each substituted with a fluorine atom.

The benzenesulfonic acid, naphthalenesulfonic acid and anthracenesulfonic acid described above may further be substituted, for example, with a halogen atom other than a fluorine atom, a hydroxy group or a nitro group.

The alkyl group bonded to the acid such as benzenesulfonic acid forming the anion of X⁻ includes, for example, an alkyl group having from 1 to 12 carbon atoms. The alkyl group may be a straight chain, branched or cyclic alkyl group. The alkyl group is substituted with at least one fluorine atom, and preferably substituted with not more than 25 fluorine atoms. Specific examples of the alkyl group include trifluoromethyl, pentafluoroethyl, 2,2,2-trifluoroethyl, heptafluoropropyl, heptafluoroisopropyl, perfluorobutyl, perfluorooctyl, perfluorododecyl and perfluorocyclohexyl groups. Of these groups, a perfluoroalkyl group having from 1 to 4 carbon atoms wherein all hydrogen atoms are replaced with fluorine atoms is preferred.

The alkoxy group bonded to the acid such as benzenesulfonic acid individually or together with the alkyl group includes an alkoxy group having from 1 to 12 carbon atoms. The alkoxy group may be a straight chain, branched or cyclic alkoxy group. The alkoxy group is substituted with at least one fluorine atom, and preferably substituted with not more than 25 fluorine atoms. Specific examples of the alkoxy group include trifluoromethoxy, pentafluoroethoxy, heptafluoroisopropyloxy, perfluorobutoxy, perfluorooctyloxy, perfluorododecyloxy and perfluorocyclohexyloxy groups. Of these groups, a perfluoroalkoxy group having from 1 to 4 carbon atoms wherein all hydrogen atoms are replaced with fluorine atoms is preferred.

The acyl group bonded to the acid such as benzenesulfonic acid individually or together with the alkyl group includes preferably an acyl group having from 2 to 12 carbon atoms and substituted with from 1 to 23 fluorine atoms. Specific examples of the acyl group include trifluoroacetyl, fluoroacetyl, pentafluoropropionyl and pentafluorobenzoyl groups.

The acyloxy group bonded to the acid such as benzenesulfonic acid individually or together with the alkyl group includes preferably an acyloxy group having form 2 to 12 carbon atoms and substituted with from 1 to 23 fluorine atoms. Specific examples of the acyloxy group include trifluoroacetoxy, fluoroacetoxy, pentafluoropropionyloxy and pentafluorobenzoyloxy groups.

The sulfonyl group bonded to the acid such as benzenesulfonic acid individually or together with the alkyl group includes preferably a sulfonyl group having from 1 to 12 carbon atoms and substituted with from 1 to 25 fluorine atoms. Specific examples of the sulfonyl group include trifluoromethanesulfonyl, pentafluoroethanesulfonyl, perfluorobutanesulfonyl, perfluorooctanesulfonyl, pentafluorobenzenesulfonyl and 4-trifluoromethylbenzenesulfonyl groups.

The sulfonyloxy group bonded to the acid such as benzenesulfonic acid individually or together with the alkyl group includes preferably a sulfonyloxy group having from 1 to 12 carbon atoms and substituted with from 1 to 25 fluorine atoms. Specific examples of the sulfonyloxy group include trifluoromethanesulfonyloxy, perfluorobutanesulfonyloxy and 4-trifluoromethylbenzenesulfonyloxy groups.

The sulfonylamino group bonded to the acid such as benzenesulfonic acid individually or together with the alkyl group includes preferably a sulfonylamino group having from 1 to 12 carbon atoms and substituted with from 1 to 25 fluorine atoms. Specific examples of the sulfonylamino group include trifluoromethanesulfonylamino, perfluorobutanesulfonylamino, perfluorooctanesulfonylamino and pentafluorobenzenesulfonylamino groups.

The aryl group bonded to the acid such as benzenesulfonic acid individually or together with the alkyl group includes preferably an aryl group having from 6 to 14 carbon atoms and substituted with from 1 to 9 fluorine atoms. Specific examples of the aryl group include pentafluorophenyl, 4-trifluoromethylphenyl, heptafluoronaphthyl, nonafluoroanthranyl, 4-fluorophenyl and 2,4-difluorophenyl groups.

The aralkyl group bonded to the acid such as benzenesulfonic acid individually or together with the alkyl group includes preferably an aralkyl group having from 7 to 10 carbon atoms and substituted with from 1 to 15 fluorine atoms. Specific examples of the aralkyl group include pentafluorophenylmethyl, pentafluorophenylethyl, perfluorobenzyl and perfluorophenthyl groups.

The alkoxycarbonyl group bonded to the acid such as benzenesulfonic acid individually or together with the alkyl group includes preferably an alkoxycarbonyl group having from 2 to 13 carbon atoms and substituted with from 1 to 25 fluorine atoms. Specific examples of the alkoxycarbonyl group include trifluoromethoxycarbonyl, pentafluoroethoxycarbonyl, pentafluorophenoxycarbonyl, perfluorobutoxycarbonyl and perfluorooctyloxycarbonyl groups.

Among the anions, more preferred X⁻ is a fluorine-substituted benzenesulfonic acid anion, and pentafluorobenzenesulfonic acid anion is particularly preferred.

The benzenesulfonic acid, naphthalenesulfonic acid and anthracenesulfonic acid having a fuluorine-containing substituent may be further substituted, for example, with a straight chain, branched or cyclic alkoxy group, an acyl group, an acyloxy group, a sulfonyl group, a sulfonyloxy group, a sulfonylamino group, an aryl group, an aralkyl group, an alkoxycarbonyl group (the ranges of carbon atom number of these groups are the same as those described above), a halogen atom (excluding fluorine), a hydroxy group or a nitro group.

Specific examples of the compounds represented by formulae (I) to (III) are set forth below, but the present invention should not be construed as being limited thereto.

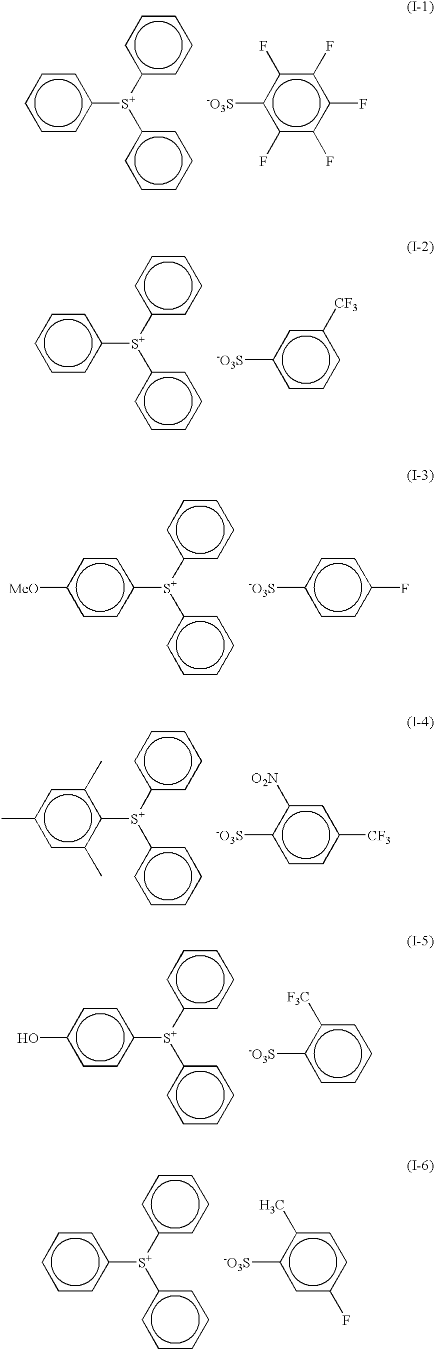

The anion of acid represented by X⁻ in formulae (I) to (III) may be an onium salt of an unsubstituted benzenesulfonic acid or a benzenesulfonic acid having a substituent other than a fluorine atom. Examples of the substituent include an alkyl group, an alkoxy group, an acyl group, an acyloxy group, an aryl group, a hydroxy group, a nitro group and a halogen atom (e.g., chlorine or bromine).

The X⁻ also may be an onium salt of an anion of an alkanesulfonic acid having from 1 to 20 carbon atoms. In such a case, an onium salt of an anion of an alkanesulfonic acid substituted with a fluorine atom is more preferred.

Further, the X⁻ may be an onium salt of an inorganic anion, for example, BF₄⁻, AsF₆⁻ or PF₆⁻.

In addition to the specific examples described above, specific examples of the compounds represented by formulae (I) to (III) and other onium salts are set forth below, but the present invention should not be construed as being limited thereto.

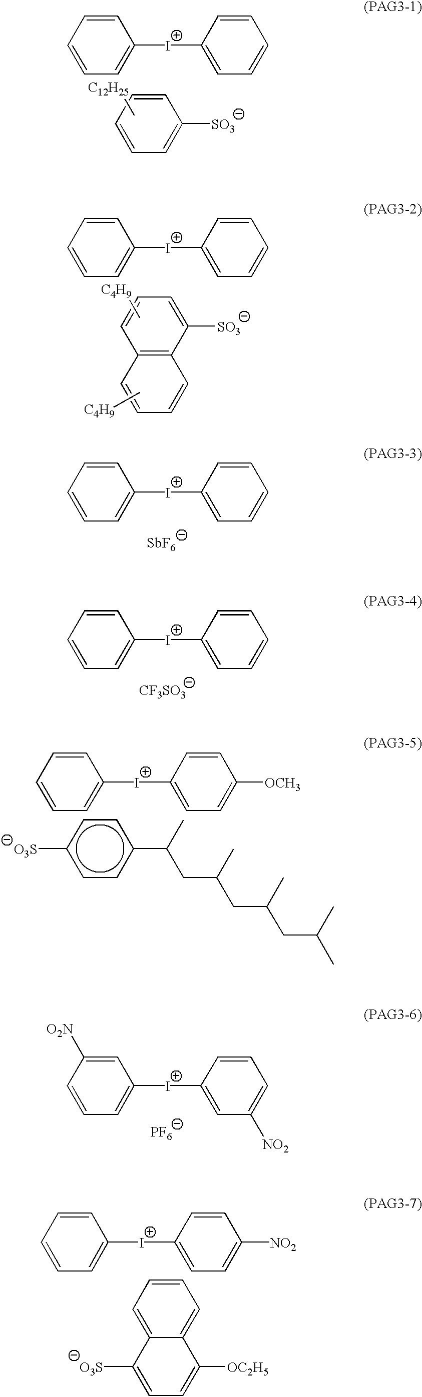

The compounds of formulae (I) and (II) can be synthesized by the following methods. For example, a method wherein an aryl Grignard reagent, e.g., arylmagnesium bromide is reacted with phenyl sulfoxide and the resulting triarylsulfonium halide is subjected to salt-exchange with a corresponding sulfonic acid is used. There is another method wherein phenyl sulfoxide and a corresponding aromatic compound are condensed using an acid catalyst, e.g., methanesulfonic acid/diphosphorus pentoxide or aluminum chloride and the product is subjected to salt-exchange. Alternatively, the compounds can be synthesized by a method wherein a diaryl iodonium salt and diaryl sulfide are condensed using a catalyst, e.g., copper acetate and the product is subjected to salt-exchange. In any one of the above-described methods, the phenyl sulfoxide may have a substituent on the benzene ring thereof or may not have such a substituent.

The compound of formula (III) can be synthesized by reacting an aromatic compound with a periodate.

Of the disulfone compound, N-imidosulfonate compound and diazodisulfone compound for the compound of component (A), the compounds represented by formulae (PAG5), (PAG6) and (PAG7) shown below are preferred, respectively.

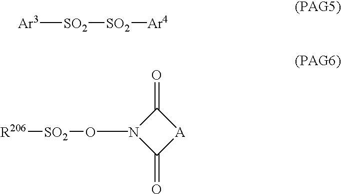

wherein Ar³ and Ar⁴ each independently represent a substituted or unsubstituted aryl group; R²⁰⁶ represents a substituted or unsubstituted alkyl group or a substituted or unsubstituted aryl group; and A represents a substituted or unsubstituted alkylene group, a substituted or unsubstituted alkenylene group or a substituted or unsubstituted arylene group.

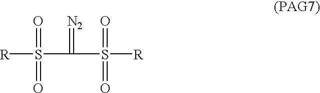

wherein R represents a straight chain, branched or cyclic alkyl group or an aryl group which may be substituted.

Specific examples of the compounds represented by formulae (PAG5), (PAG6) and (PAG7) are set forth below, but the present invention should not be construed as being limited thereto.

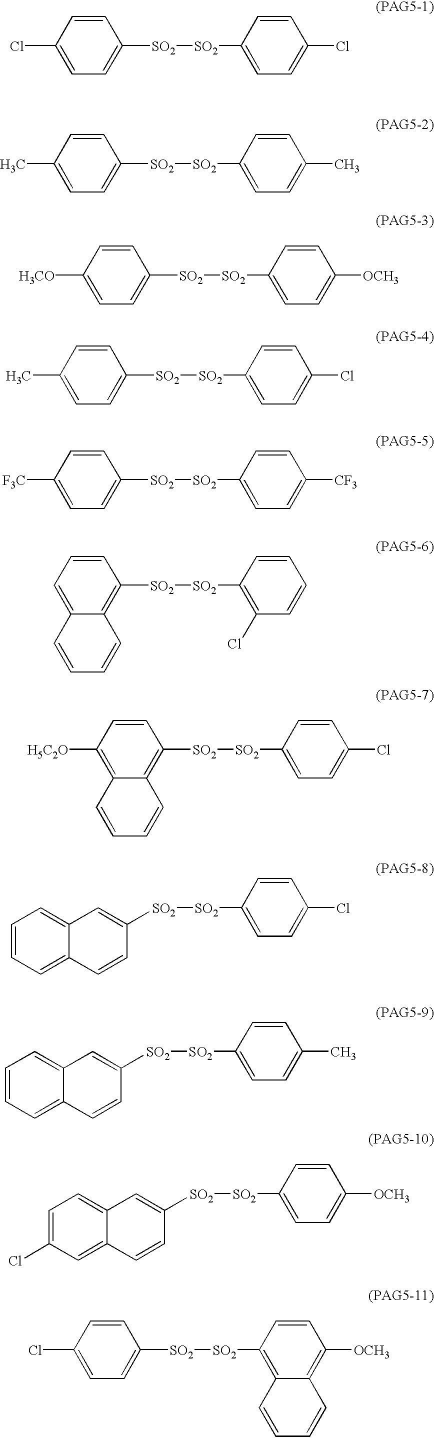

The amount of the compound of component (A) for use in the present invention is ordinarily from 0 to 20% by weight, preferably from 0.5 to 10% by weight, and more preferably from 1 to 7% by weight, based on the solid content of the positive resist composition.

With respect to a ratio of the compound of component (A) and the compound of component (C), a weight ratio of the compound of component (C)/the compound of component (A) is ordinarily from 100/0 to 5/95, preferably from 100/0 to 10/90, and particularly preferably from 100/0 to 20/80.

Other components for use in the positive resist composition of the present invention are described below.

Into the positive resist composition of the present invention, other components, for example, a nitrogen-containing basic compound, a dye and a surface active agent may be incorporated, if desired.

Nitrogen-Containing Basic Compound

The nitrogen-containing basic compound of component (E) for use in the present invention is preferably a nitrogen-containing basic compound having the basicity stronger than that of phenol.

A preferred chemical environment includes a structure represented by the following formula (A), (B), (C), (D) or (E):

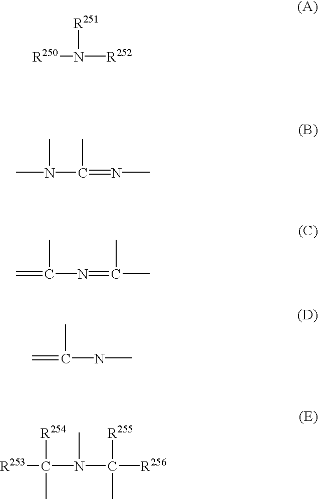

wherein R²⁵⁰, R²⁵¹ and R²⁵², which may be the same or different, each represent a hydrogen atom, an alkyl group having from 1 to 6 carbon atoms, an aminoalkyl group having from 1 to 6 carbon atoms, a hydroxyalkyl group having from 1 to 6 carbon atoms or a substituted or unsubstituted aryl group having from 6 to 20 carbon atoms, or R²⁵¹ and R²⁵² may combine with each other to form a ring; R²⁵³, R²⁵⁴ R²⁵⁵ and R²⁵ which may be the same or different, each represent an alkyl group having from 1 to 6 carbon atoms.

A more preferable compound is a nitrogen-containing basic compound having at least two nitrogen atoms of different chemical environments in the molecule thereof. A compound containing both a substituted or unsubstituted amino group and a ring structure containing a nitrogen atom, and a compound containing an alkylamino group are particularly preferred.

Preferred specific examples of the nitrogen-containing basic compound include a substituted or unsubstituted guanidine, a substituted or unsubstituted aminopyridine, a substituted or unsubstituted aminoalkylpyridine, a substituted or unsubstituted aminopyrrolidine, a substituted or unsubstituted indazole, a substituted or unsubstituted imidazole, a substituted or unsubstituted pyrazole, a substituted or unsubstituted pyrazine, a substituted or unsubstituted pyrimidine, a substituted or unsubstituted purine, a substituted or unsubstituted imidazoline, a substituted or unsubstituted pyrazoline, a substituted or unsubstituted piperazine, a substituted or unsubstituted aminomorpholine and a substituted or unsubstituted aminoalkylmorpholine. Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxy group and a cyano group.

Particularly preferable compounds include guanidine, 1,1-dimethylguanidine, 1,1,3,3-tetramethylguanidine, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine and N-(2-aminoethyl)morpholine. However, the present invention should not be construed as being limited to these compounds. The nitrogen-containing basic compounds may be used individually or in combination of two or more thereof.

With respect to a ratio of the acid generator and the nitrogen-containing basic compound used in the resist composition, a molar ratio of the acid generator/the nitrogen-containing basic compound is preferably from 2.5 to 300. When the molar ratio is less than 2.5, the resolution is decreased in some cases. On the other hand, when the molar ratio exceeds 300, the resist pattern sizes are increased with the passage of time from light exposure to heat treatment, and the resolution is also decreased in some cases. The molar ratio of the acid generator/the nitrogen-containing basic compound is more preferably from 5.0 to 200, and still more preferably from 7.0 to 150.

Dye

A suitable dye includes an oil dye and a basic dye. Specific examples of the dye include Oil Yellow #101, Oil Yellow #103, Oil Pink #312, Oil Green BG, Oil Blue BOS, Oil Blue #603, Oil Black BY, Oil Black BS, Oil Black T-505 (these dyes are manufactured by Orient Chemical Industries, Ltd.), Crystal Violet (CI 42555), Methyl Violet (CI 42535), Rhodamine B (CI 45170B), Malachite Green (CI 42000) and Methylene Blue (CI 52015).

Solvent

The resist composition of the present invention is dissolved in a solvent capable of dissolving the components described above and applied to a support. Preferred examples of the solvent used include ethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methylpyruvate, ethyl pyruvate, propyl pyruvate, N,N-dimethylformamide, dimethyl sulfoxide, N-methylpyrrolidone and tetrahydrofuran. The solvents may be used individually or as a mixture of two or more thereof.

Surface Active Agent

A surface active agent may be added to the solvent described above. Specifically, the surface active agent for use in the resist composition of the present invention includes a nonionic surface active agent, for example, a polyoxyethylene alkyl ether, e.g., polyoxyethylene lauryl ether, polyoxyethylene stearyl ether, polyoxyethylene cetyl ether or polyoxyethylene oleyl ether, a polyoxyethylene alkylaryl ether, e.g., polyoxyethylene octylphenol ether or polyoxyethylene nonylphenol ether, a polyoxyethylene-polyoxypropylene block copolymer, a sorbitan fatty acid ester, e.g., sorbitan monolaurate, sorbitan monopalmitate, sorbitan monostearate, sorbitan monooleate, sorbitan trioleate or sorbitan tristearate, a polyoxyethylene sorbitan fatty acid ester, e.g., polyoxyethylene sorbitan monolaurate, polyoxyethylene sorbitan monopalmitate, polyoxyethylene sorbitan monostearate, polyoxyethylene sorbitan trioleate or polyoxyethylene sorbitan tristearate; a fluorine-base or silicon-base surface active agent, e.g., Eftop EF 301, EF 303 and EF 352 (manufactured by Shin Akita Kasei Co., Ltd.), Megafac F171 and F173 (manufactured by Dainippon Ink & Chemicals, Inc.), Florad FC430 and FC431 (manufactured by Sumitomo 3M Ltd.), Asahiguard AG710, Surflon S-382, SC101, SC102, SC103, SC104, SC105 and SC106 (manufactured by Asahi Glass Co., Ltd.), Troysol S-366 (manufactured by Troy Chemical Corp.); an organosiloxane polymer (KP341, manufactured by Shin-Etsu Chemical Co., Ltd.) and an acrylic acid or methacrylic acid (co)polymer (Polyflow No. 75 and No. 95, manufactured by Kyoeisha Chemical Co., Ltd.).

The amount of the surface active agent used is usually not more than 2 parts by weight, and preferably not more than 1 part by weight per 100 parts by weight of the solid content of the resist composition of the present invention.

The surface active agents may be used individually or in combination of two or more thereof.

The pattern formation process on a resist film in the production of precision integrated circuit element comprises applying the positive resist composition of the present invention to a substrate (for example, a silicon/silicon dioxide film or a transparent substrate, e.g., a glass substrate or an ITO substrate), irradiating the coated layer with an active ray or radiation, heating, developing, rinsing and drying the coated layer to form a good resist pattern. The active ray or radiation used includes preferably an electron beam, an X ray and an excimer laser beam having a wavelength of from 150 to 250 nm (e.g., KrF excimer laser (248 nm), ArF excimer laser (193 nm) or F₂ excimer laser (157 nm)), and particularly preferably an electron beam or a KrF excimer laser.

In the present invention, a known inorganic or organic reflection preventing coating may be used, if desired. Further, the reflection preventing coating may be applied to the resist layer.

Suitable examples of the reflection preventing coating used for an under layer of the resist layer include an inorganic coating type, for example, titanium, titanium dioxide, titanium nitride, chromium oxide, carbon or amorphous silicon, and an organic coating type comprising a light absorbent and a polymer material. The former requires an apparatus, for example, a vacuum deposition apparatus, a CVD apparatus or a sputtering apparatus, for the formation of reflection preventing coating. The organic reflection preventing coating includes, for example, a coating comprising a condensate of a diphenylamine derivative with a formaldehyde-modified melamine resin, an alkali-soluble resin and a light absorbent as described in JP-B-7-69611 (the term “JP-B” as used herein means an “examined Japanese patent publication”), a coating comprising a reaction product of a maleic anhydride copolymer with a diamine light absorbent as described in U.S. Pat. No. 5,294,680, a coating comprising a resin binder and a methylolmelamine thermal crosslinking agent as described in JP-A-6-118631, a coating comprising an acrylic resin containing a carboxylic acid group, an epoxy group and a light absorbing group within the same molecule as described in JP-A-6-118656, a coating comprising methylolmelamine and a benzophenone light absorbent as described in JP-A-8-87115, and a coating comprising a low molecular weight light absorbent added to a polyvinyl alcohol resin as described in JP-A-8-179509.

Also, a commercially available organic reflection preventing coating, for example, DUV-30 Series and DUV-40 Series (manufactured by Brewer Science, Inc.) and AR-2, AR-3 and AR-5 (manufactured by Shipley Co., Ltd.) are employed as the organic reflection preventing coating.

A developer for the positive resist composition of the present invention is ordinarily an aqueous solution of an alkali, for example, an inorganic alkali, e.g., sodium hydroxide, potassium hydroxide, sodium carbonate, sodium silicate, sodium metasilicate or aqueous ammonia; a primary amine, e.g., ethylamine or n-propylamine; a secondary amine, e.g., diethylamine or di-n-butylamine; a tertiary amine, e.g., triethylamine or methyldiethylamine; an alcoholamine, e.g., dimethylethanolamine or triethanolamine; a quaternary ammonium salt, e.g., tetramethylammonium hydroxide, tetraethylammonium hydroxide or choline; and a cyclic amine, e.g., pyrrole or piperidine. Further, an appropriate amount of an alcohol, e.g., isopropyl alcohol or a surface active agent, e.g., a nonionic surface active agent may be added to the aqueous solution of alkali.

Of the developers, a developer containing a quaternary ammonium salt is preferred, and a developer containing tetramethylammonium hydroxide or choline is more preferred.

The negative resist composition according to the present invention is described in detail below.

The negative resist composition of the present invention contains an alkali-soluble polymer (component (F)) in addition to the compound of component (C).

Alkali-Soluble Polymer of Component (F)

The alkali-soluble polymer of component (F) for use in the negative resist composition of the present invention includes polymers having a phenol skeleton which have hitherto been disclosed in the field of chemically amplified negative resists, for example, a phenol novolak resin, a polyvinylphenol resin, a copolymer having a structural unit originated in vinylphenol and a resin obtained by partially protecting or modifying a polyvinylphenol resin. A phenol resin containing a repeating structural unit represented by the above-described formula (b) is preferably used.

In formula (b), R₁ represents a hydrogen atom, a halogen atom, a cyano group or an alkyl group which may have a substituent.

R₂ represents a hydrogen atom, an alkyl group which may have a substituent, a cycloalkyl group which may have a substituent, an aryl group which may have a substituent, an aralkyl group which may have a substituent or an acyl group which may have a substituent.

R₃ and R₄, which may be the same or different, each represent a hydrogen atom, a halogen atom, a cyano group, an alkyl group which may have a substituent, a cycloalkyl group which may have a substituent, an alkenyl group which may have a substituent, an aralkyl group which may have a substituent or an aryl group which may have a substituent. When both R₃ and R₄ represent hydrogen atoms, the R₃ and R₄ do not constitute substituents on the benzene ring of formula (b).

A represents a single bond, an alkylene group which may have a substituent, an alkenylene group which may have a substituent, a cycloalkylene group which may have a substituent or an arylene group which may have a substituent, —O—, —SO₂—, —O—CO—R₅—, —CO—O—R₆— or —CO—N(R₇) —R₈—.

R₅, R₆ and R₈, which may be the same or different, each represent a single bond, an alkylene group which may have a substituent, an alkenylene group which may have a substituent, a cycloalkylene group which may have a substituent, an arylene group which may have a substituent, or a divalent group formed by combining the above-described alkylene, alkenylene, cycloalkylene or arylene group with at least one member selected from an ether structure, an ester structure, an amide structure, a urethane structure and a ureido structure.

R₇ represents a hydrogen atom, an alkyl group which may have a substituent, a cycloalkyl group which may have a substituent, an aralkyl group which may have a substituent or an aryl group which may have a substituent. n represents an integer of from 1 to 3. Also, plural R₂'s, or R₂ and R₃ or R₄ may combine with each other to form a ring.

The alkyl group for R₁ to R₄ and R₇ preferably includes an alkyl group having from 1 to 8 carbon atoms, specifically, methyl, ethyl, propyl, n-butyl, sec-butyl, hexyl, 2-ethylhexyl and octyl groups.

The cycloalkyl group for R₂ to R₄ and R₇ may be a monocyclic or polycyclic cycloalkyl group. The monocyclic cycloalkyl group preferably includes those having from 3 to 8 carbon atoms, specifically, cyclopropyl, cyclopentyl and cyclohexyl groups. The polycyclic cycloalkyl group preferably includes adamantyl, norbornyl, isobornyl, dicyclopentyl, α-pinenyl and tricyclodecanyl groups.

The alkenyl group for R₃ and R₄ preferably includes an alkenyl group having from 2 to 8 carbon atoms, specifically, vinyl, allyl, butenyl and cyclohexenyl groups.

The aryl group for R₂ to R₄ and R₇ preferably includes an aryl group having from 6 to 15 carbon atoms, specifically, phenyl, tolyl, dimethylphenyl, 2,4,6-trimethylphenyl, naphthyl and anthryl groups.

The aralkyl group for R₂ to R₄ and R₇ preferably includes an aralkyl group having from 7 to 12 carbon atoms, specifically, benzyl, phenethyl and naphthylmethyl groups.

The acyl group for R₂ preferably includes an acyl group having from 1 to 8 carbon atoms, specifically, formyl, acetyl, propanoyl, butanoyl, pivaloyl and benzoyl groups. The alkylene group for A, R₅, R₆ and R₈ preferably includes an alkylene group having from 1 to 8 carbon atoms, e.g., methylene, ethylene, propylene, butylene, hexylene and octylene groups, which may have a substituent.

The alkenylene group for A, R₅, R₆ and R₈ preferably includes an alkenylene group having from 2 to 6 carbon atoms, e.g., ethenylene, propenylene and butenylene groups, which may have a substituent.

The cycloalkylene group for A, R₅, R₆ and R₈ preferably includes a cycloalkylene group having from 5 to 8 carbon atoms, e.g., cyclopentylene and cyclohexylene groups, which may have a substituent.

The arylene group for A, R₅, R₆ and R₈ preferably includes an arylene group having from 6 to 12 carbon atoms, e.g., phenylene, tolylene and naphthylene groups.

The alkyl group, cycloalkyl group, aryl group, aralkyl group, acyl group, alkenyl group, alkenylene group, cycloalkylene group and arylene group described above may have a substituent.

The substituent for the above-described groups includes a group having an active hydrogen, for example, an amino group, an amido group, a ureido group, a urethane group, a hydroxy group or a carboxy group; a halogen atom (e.g., fluorine, chlorine, bromine or iodine atom), an alkoxy group (e.g., methoxy, ethoxy, propoxy or butoxy group), a thioether group, an acyl group (e.g., acetyl, propanoyl or benzoyl group), an acyloxy group (e.g., acetoxy, propanoyloxy or benzoyloxy group), an alkoxycarbonyl group (e.g., methoxycarbonyl, ethoxycarbonyl or propoxycarbonyl group), a cyano group and a nitro group. Particularly, a group having an active hydrogen, for example, an amino group, a hydroxy group or a carboxy group is preferred.

The ring formed by combining plural R₂'s, or R₂ and R₃ or R₄ with each other includes 4-membered to 7-membered rings containing an oxygen atom, for example, benzofuran, benzodioxonol or benzopyran ring.

The alkali-soluble polymer of component (F) for use in the present invention may be a polymer composed of the repeating structural unit represented by formula (b) alone. For the purpose of further improving performance of the negative resist composition of the present invention, the alkali-soluble polymer may be a copolymer with one or more other polymerizable monomers.

The copolymerizable monomers which can be used in the present invention include, for example, compounds having one addition-polymerizable unsaturated bond selected from acrylic acid esters, acrylamides, methacrylic acid esters, methacrylamides, allyl compounds, vinyl ethers, vinyl esters, styrenes and crotonic acid esters, other than the monomers corresponding to the repeating structural units represented by formula (b).

Specific examples of the acrylic acid ester include an alkyl (number of carbon atoms in the alkyl group is preferably from 1 to 10) acrylate (e.g., methyl acrylate, ethyl acrylate, propyl acrylate, tert-butyl acrylate, amyl acrylate, cyclohexyl acrylate, ethylhexyl acrylate, octyl acrylate, tert-octyl acrylate, chloroethyl acrylate, 2-hydroxyethyl acrylate, 2,2-dimethyl-3-hydroxypropyl acrylate, 5-hydroxypentyl acrylate, trimethylolpropane monoacrylate, pentaerythritol monoacrylate, glycidyl acrylate, benzyl acrylate, furfuryl acrylate or tetrahydrofurfuryl acrylate) and an aryl acrylate (e.g., phenyl acrylate).

Specific examples of the methacrylic acid ester include an alkyl (number of carbon atoms in the alkyl group is preferably from 1 to 10) methacrylate (e.g., methyl methacrylate, ethyl methacrylate, propyl methacrylate, isopropyl methacrylate, tert-butyl methacrylate, amyl methacrylate, hexyl methacrylate, cyclohexyl methacrylate, benzyl methacrylate, chlorobenzyl methacrylate, octyl methacrylate, 2-hydroxyethyl methacrylate, 4-hydroxybutyl methacrylate, 5-hydroxypentyl methacrylate, 2,2-dimethyl-3-hydroxypropyl methacrylate, trimethylolpropane monomethacrylate, pentaerythritol monomethacrylate, glycidyl methacrylate, furfuryl methacrylate or tetrahydrofurfuryl methacrylate) and an aryl methacrylate (e.g., phenyl methacrylate, cresyl methacrylate or naphthyl methacrylate).

Specific examples of the acrylamide include acrylamide, an N-alkylacrylamide (the alkyl group preferably has from 1 to 10 carbon atoms, for example, methyl, ethyl, propyl, butyl, tert-butyl, heptyl, octyl, cyclohexyl, benzyl or hydroxyethyl group), an N-arylacrylamide (the aryl group includes, for example, phenyl, tolyl, nitrophenyl, naphthyl, cyanophenyl, hydroxyphenyl or carboxyphenyl group), an N,N-dialkylacrylamide (the alkyl group preferably has from 1 to 10 carbon atoms, for example, methyl, ethyl, butyl, isobutyl, ethylhexyl or cyclohexyl group), an N,N-diarylacrylamide (the aryl group includes, for example, phenyl group), N-methyl-N-phenylacrylamide, N-hydroxyethyl-N-methylacrylamide and N-2-acetamidoethyl-N-acetylacrylamide.

Specific examples of the methacrylamide include methacrylamide, an N-alkylmethacrylamide (the alkyl group preferably has from 1 to 10 carbon atoms, for example, methyl, ethyl, tert-butyl, ethylhexyl, hydroxyethyl or cyclohexyl group), an N-arylmethacrylamide (the aryl group includes, for example, phenyl group), an N,N-dialkylmethacrylamide (the alkyl group includes, for example, ethyl, propyl or butyl group), an N,N-diarylmethacrylamides (the aryl group include, for example, phenyl group), N-hydroxyethyl-N-methylmethacrylamide, N-methyl-N-phenylmethacrylamide and N-ethyl-N-phenylmethacrylamide.

Specific examples of the allyl compound include an allyl ester (e.g., allyl acetate, allyl caproate, allyl caprylate, allyl laurate, allyl palmitate, allyl stearate, allyl benzoate, allyl acetoacetate or allyl lactate) and allyloxy ethanol.

Specific examples of the vinyl ether include an alkyl vinyl ether (e.g., hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether or tetrahydrofurfuryl vinyl ether) and a vinyl aryl ether (e.g., vinyl phenyl ether, vinyl tolyl ether, vinyl chlorophenyl ether, vinyl 2,4-dichlorophenyl ether, vinyl naphthyl ether or vinyl anthranyl ether).

Specific examples of the vinyl ester include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl β-phenylbutyrate, vinyl cyclohexanecarboxylate, vinyl benzoate, vinyl salicylate, vinyl chlorobenzoate, vinyl tetrachlorobenzoate and vinyl naphthoate.

Specific examples of the styrene include styrene, an alkylstyrene (e.g., methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene or acetoxymethylstyrene), an alkoxystyrene (e.g., methoxystyrene, 4-methoxy-3-methylstyrene or dimethoxystyrene), a halogenostyrene (e.g., chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene or 4-fluoro-3-trifluoromethylstyrene) and carboxystyrene.

Specific examples of the crotonic acid ester include an alkyl crotonate (e.g., butyl crotonate, hexyl crotonate or glycerol monocrotonate).

Other copolymerizable monomers used include a dialkyl itaconate (e.g., dimethyl itaconate, diethyl itaconate or dibutyl itaconate), a dialkyl ester of maleic acid or fumaric acid (e.g., dimethyl maleate or dibutyl fumalate), maleic anhydride, maleimide, acrylonitrile, methacrylonitrile and maleonitrile. In addition, other copolymerizable addition-polymerizable unsaturated compounds may be generally used.

Of the monomers, a monomer improving the solubility in alkali, for example, a monomer having a carboxy group, e.g., carboxystyrene, N-(carboxyphenyl)acrylamide or N-(carboxyphenyl)methacrylamide, or maleimide is preferably used as the copolymer component.

The content of other monomers in the alkali-soluble polymer of component (F) is preferably not more than 50% by mole, and more preferably not more than 30% by mole, based on the total repeating units.

Specific examples of the polymer having the repeating structural unit represented by formula (b) are set forth below, but the present invention should not be construed as being limited thereto.

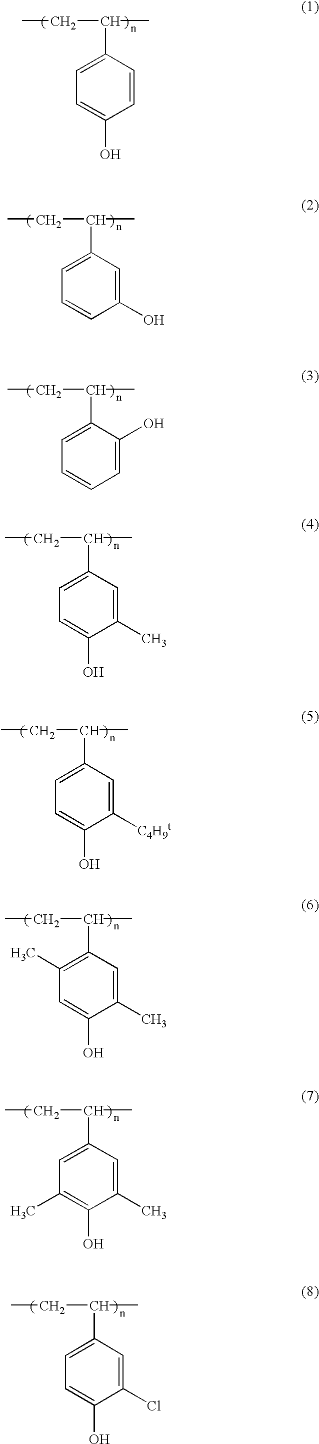

In the specific examples of the polymer described above, n represents a positive integer, and x, y and z each represent a molar ratio of each repeating unit. In the polymers composed of two components, x and y are used in the range of x=10 to 95 and y=5 to 90, and preferably x=40 to 90 and y=10 to 60. In the polymers composed of three components, x, y and z are used in the range of x=10 to 90, y=5 to 85 and z=5 to 85, and preferably x=40 to 80, y=10 to 50 and z=10 to 50.

The molecular weight of the alkali-soluble polymer of component (F), preferably the polymer having the repeating structural unit represented by formula (b), is preferably in a range of from 1,000 to 200,000, and more preferably from 3,000 to 50,000 in terms of a weight average molecular weight. The molecular weight distribution of the polymer is in the range of from 1 to 10, preferably from 1 to 3, and more preferably from 1 to 1.5. As the molecular weight distribution is smaller, the resolution is higher, the pattern profile is better, the sidewalls of the resist patterns are smoother, and the resist patterns are excellent in the roughness property.

The content of the repeating structural unit represented by formula (b) is from 5 to 100% by mole, and preferably from 10 to 90% by mole, based on the total polymers.

The alkali-soluble polymer containing the repeating structural unit represented by formula (b) for use in the present invention can be synthesized by methods as described in Macromolecules, 28(11), pages 3787 to 3789 (1995), Polym. Bull. (Berlin), 24(4), pages 385 to 389 (1990) and JP-A-8-286375. Specifically, the desired alkali-soluble polymer can be obtained by a radical polymerization method or a living anion polymerization method.

The alkali-soluble polymers may be used individually or as a mixture of two or more thereof.

The weight average molecular weight is a value determined by gel permeation chromatography and indicated in terms of polystyrene.

The alkali-dissolving rate of the alkali-soluble polymer is preferably not less than 20 angstrom/second, and particularly preferably not less than 200 angstrom/second, measured with 0.261N tetramethylammonium hydroxide (TMAH) at 23° C.

The alkali-soluble polymer containing a repeating unit represented by formula (b) according to the present invention may be used individually or together with alkali-soluble polymers other than the polymer containing a repeating unit represented by formula (b). The amount of other alkali-soluble polymers used is at most 100 parts by weight based on 100 parts by weight of the alkali-soluble polymer containing a repeating unit represented by formula (b) of the present invention. Examples of other alkali-soluble polymers used in combination include a novolak resin, a hydrogenated novolak resin, an acetone-pyrogallol resin, a styrene-maleic anhydride copolymer, a carboxy group-containing methacrylic resin and a derivative thereof, but the present invention should not be construed as being limited thereto.

The amount of the polymer of component (F) is in a range of from 30 to 95% by weight, preferably from 40 to 90% by weight, and more preferably from 50 to 80% by weight, based on the total solid content of the resist composition.

The alkali-soluble polymer of component (F) for use in the present invention preferably includes a polymer having a repeating unit represented by formula (b-2) or (b-3) described above.

In formulae (b-2) and (b-3), R₁ has the same meaning as R₁ in formula (b).

A has the same meaning as A in formula (b).

R₁₀₁ to R₁₀₆ each independently represent a hydroxy group, a carboxy group, an amino group, an alkyl group which may have a substituent, a cycloalkyl group which may have a substituent, an alkoxy group which may have a substituent, an alkylcarbonyloxy group which may have a substituent, an alkylsulfonyloxy group which may have a substituent, an alkenyl group which may have a substituent, an aryl group which may have a substituent, an aralkyl group which may have a substituent, an N-alkylamino group which may have a substituent or an N-dialkylamino group which may have a substituent, preferably a hydroxy group, a straight chain or branched alkyl group having from 1 to 6 carbon atoms, an alkoxy group having from 1 to 6 carbon atoms, an alkylcarbonyloxy group having from 1 to 6 carbon atoms or a phenyl group, and more preferably a hydroxy group, a straight chain or branched alkyl group having from 1 to 4 carbon atoms (e.g., methyl, ethyl, n-propyl, n-butyl or tert-butyl group), an alkoxy group having from 1 to 3 carbon atoms (e.g., methoxy or ethoxy group) or a phenyl group.

a to f each represent an integer of from 0 to 3, preferably an integer of from 0 to 2.

The straight chain or branched alkyl group in the alkyl group, alkoxy group, alkylcarbonyloxy group, alkylsulfonyloxy group, N-alkylamino group or N-dialkylamino group preferably includes methyl, ethyl, propyl, n-butyl, sec-butyl, hexyl, 2-ethylhexyl and octyl groups. The cyclic alkyl group may be a monocyclic or polycyclic cycloalkyl group. The monocyclic cycloalkyl group preferably includes cyclopropyl, cyclopentyl and cyclohexyl groups. The polycyclic cycloalkyl group preferably includes adamantyl, norbornyl, isobornyl, dicyclopentyl, α-pinenyl and tricyclodecanyl groups.

The alkenyl group preferably includes vinyl, allyl, butenyl and cyclohexenyl groups.

The aryl group preferably includes phenyl, tolyl, dimethylphenyl, 2,4,6-trimethylphenyl, naphthyl and anthryl groups.

The aralkyl group preferably includes benzyl, phenethyl and naphthylmethyl groups.

Y represents a condensed polycyclic aromatic structure selected from those described above.

In the condensed polycyclic aromatic structure represented by Y, the position of bond connecting to the main chain of the polymer or the position of bond connecting to a substituent may be any position on the condensed polycyclic aromatic structure.

The alkyl group, cycloalkyl group, aryl group, alkoxy group, alkylcarbonyloxy group, alkylsulfonyloxy group, aralkyl group, alkenyl group, N-alkylamino group or N-dialkylamino group described above may have a substituent.

The substituent for the above-described groups includes a group having an active hydrogen, for example, an amino group, an amido group, a ureido group, a urethane group, a hydroxy group or a carboxy group; a halogen atom (e.g., fluorine, chlorine, bromine or iodine atom), an alkoxy group (e.g., methoxy, ethoxy, propoxy or butoxy group), a thioether group, an acyl group (e.g., acetyl, propanoyl or benzoyl group), an acyloxy group (e.g., acetoxy, propanoyloxy or benzoyloxy group), an alkoxycarbonyl group (e.g., methoxycarbonyl, ethoxycarbonyl or propoxycarbonyl group), a cyano group and a nitro group. The content of the repeating unit represented by formulae (b-2) and/or (b-3) in the alkali-soluble polymer for use in the present invention is preferably from 3 to 50% by mole, and more preferably 5 to 40% by mole, based on the total repeating units.

Specific examples of the alkali-soluble polymer having a condensed polycyclic aromatic structure for use in the present invention are set forth below, but the present invention should not be construed as being limited thereto.

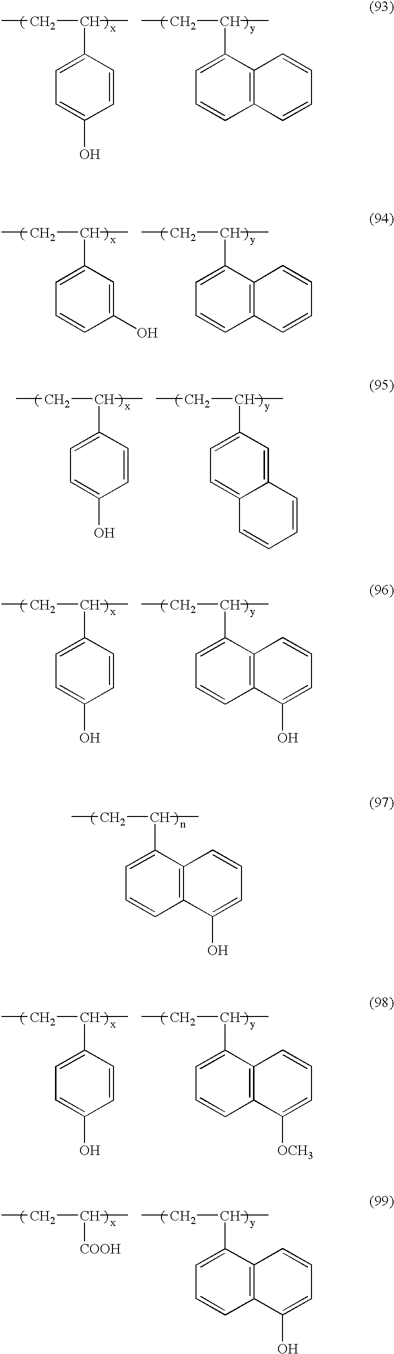

Of the alkali-soluble polymers of component (F) for use in the present invention, a copolymer having a repeating unit containing a monocyclic aromatic structure and a repeating unit containing a polycyclic aromatic structure is more preferred.

Crosslinking Agent of Component (G) for Use in the Negative Resist Composition of the Present Invention

In the negative resist composition according to the present invention, a compound of component (G) crosslinking by the action of an acid (hereinafter, referred to as “an acid crosslinking agent” or simply “a crosslinking agent” sometimes) is used together with the alkali-soluble resin of component (F) and the compound of component (C). In the present invention, a known acid crosslinking agent can be effectively used.

Preferred examples of the acid crosslinking agent for use in the present invention include compounds or resins having at least two groups selected from a hydroxymethyl group, an alkoxymethyl group, an acyloxymethyl group and an alkoxymethyl ether group, and epoxy compounds.

More preferred examples thereof include alkoxymethylated or acyloxymethylated melamine compounds or resins, alkoxymethylated or acyloxymethylated urea compounds or resins, hydroxymethylated or alkoxymethylated phenol compounds or resins, and alkoxymethyl-etherified phenol compounds or resins.

Specifically, a phenol derivative can be used as the crosslinking agent. A phenol derivative having a molecular weight of not more than 1,200, containing from 3 to 5 benzene rings in the molecule thereof, and having at least two groups selected from a hydroxymethyl group and an alkoxymethyl group is preferably used. In the phenol derivative, the hydroxymethyl group and alkoxymethyl group may be connected concentrically to one of the benzene rings or dispersedly to the benzene rings. By using such a phenol derivative, the effects of the present invention can be more remarkably achieved.

The alkoxymethyl group connected to the benzene ring preferably includes an alkoxymethyl group having not more than 6 carbon atoms. Specific examples of the alkoxymethyl group include methoxymethyl, ethoxymethyl, n-propoxymethyl, isopropoxymethyl, n-butoxymethyl, isobutoxymethyl, sec-butoxymethyl and tert-butoxymethyl groups. An alkoxy-substituted alkoxy group, e.g., 2-methoxyethoxy group is also preferred.

Of the phenol derivatives, those particularly preferred are shown below.

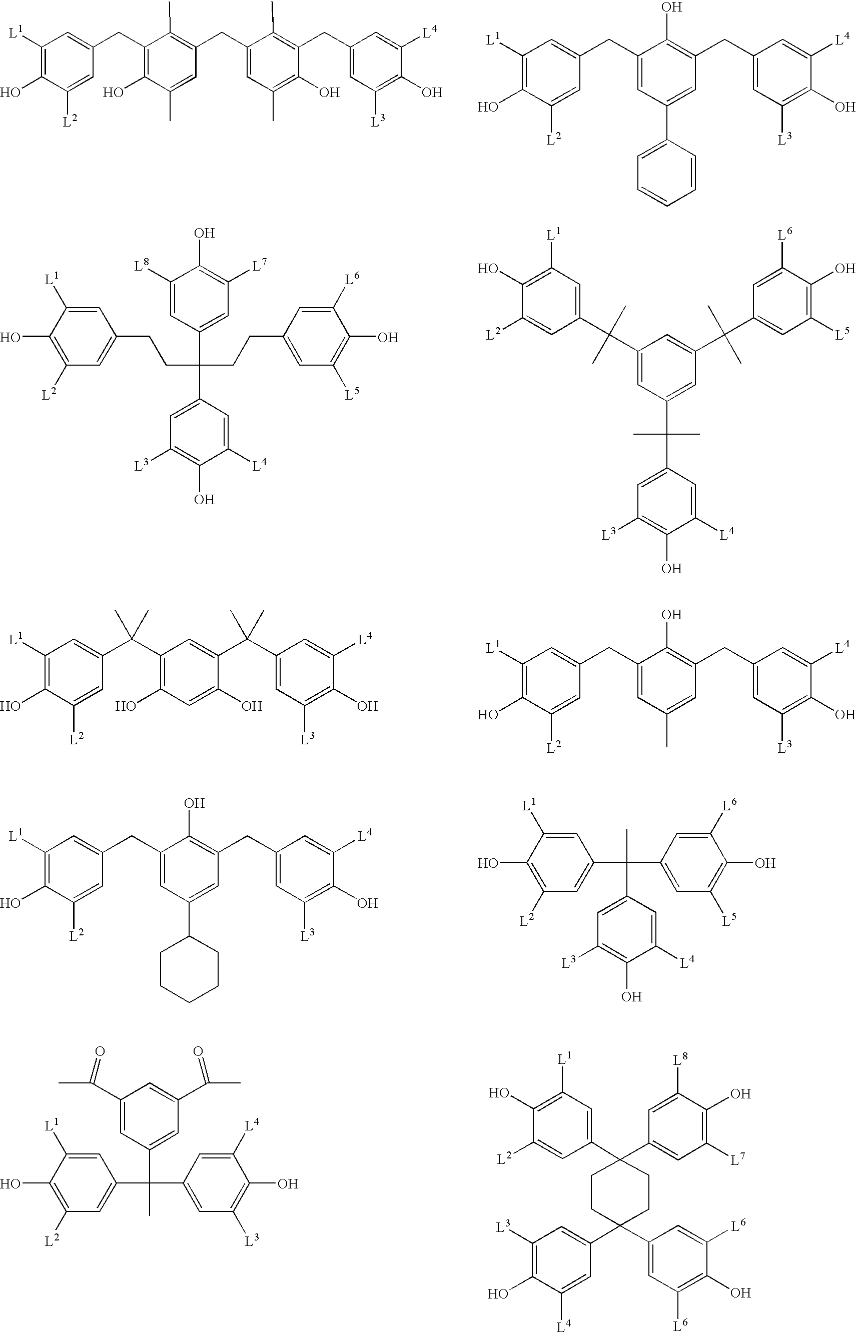

wherein, L¹ to L⁸, which may be the same or different, each represent a hydroxymethyl group, a methoxymethyl group or an ethoxymethyl group.

The phenol derivative having a hydroxymethyl group can be obtained by reacting a corresponding phenol compound having no hydroxymethyl group (the compound represented by the above-described formula wherein all of L¹ to L⁸ represent hydrogen atoms) with formaldehyde in the presence of a base catalyst. At that time, it is preferred to carry out the reaction at a temperature of not higher than 60° C. in order to prevent the occurrence of resinification or gelation. Specifically, the phenol derivative can be synthesized according to methods described, e.g., in JP-A-6-282067 and JP-A-7-64285.

The phenol derivative having an alkoxymethyl group can be obtained by reacting a corresponding phenol derivative having a hydroxymethyl group with an alcohol in the presence of an acid catalyst. At that time, it is preferred to carry out the reaction at a temperature of not higher than 100° C. in order to prevent the occurrence of resinification or gelation. Specifically, the phenol derivative can be synthesized according to methods described, e.g., in European Patent 632,003.

The phenol derivatives having a hydroxymethyl group or an alkoxymethyl group synthesized as described above are preferable in view of the storage stability, and the phenol derivatives having an alkoxymethyl group are particularly preferable from the standpoint of storage stability.

The phenol derivatives having at least two groups selected from a hydroxymethyl group and an alkoxymethyl group in total, wherein these groups are connected concentrically to one of the benzene rings or dispersedly to the benzene rings, may be used individually or in combination of two or more thereof.

Other than the above-described phenol derivatives, compounds (i) and (ii) shown below can also be used as the crosslinking agents.

(i) Compounds having an N-hydroxymethyl group, an N-alkoxymethyl group or an N-acyloxymethyl group

(ii) Epoxy compounds

The crosslinking agent is used in an amount of from 3 to 65% by weight, and preferably from 5 to 50% by weight, base on the total solid content of the resist composition. When the amount of the crosslinking agent added is less than 3% by weight, a remaining ratio of the resist film is lowered, and on the other hand, when the amount exceeds 65% by weight, the resolution is decreased and a further disadvantage in stability of the resist solution during storage may occur.

In the present invention, in addition to the phenol derivative, other crosslinking agents, for example, the crosslinking agent (i) or (ii) described above may be used in combination.

The amount of other crosslinking agents, which can be used in combination with the phenol derivative, is ordinarily from 100/0 to 20/80, preferably 90/10 to 40/60, and more preferably from 80/20 to 50/50, in a molar ratio of the phenol derivative/other crosslinking agents.

These crosslinking agents are described in detail below.

(i) Examples of the compound having an N-hydroxymethyl group, an N-alkoxymethyl group or an N-acyloxymethyl group include alkylated hexamethoxymelamine compounds as described in European Patent Laid Open No. (hereinafter, referred to as “EP-A”) 133,216, oligomer-hexamethoxymelamine-formaldehyde condensates as described in West German Patent 3,634,371, urea crosslinking agents having a melamine skeleton condensates as described in West German Patent 3,711,264, and alkoxy-substituted benzoguanamine-formaldehyde condensates as described in EP-A-212,482.

Preferred examples thereof include a melamine-formaldehyde derivative having at least two groups selected from free N-hydroxymethyl group, N-alkoxymethyl group and N-acyloxymethyl group. The melamine-formaldehyde derivative having N-alkoxymethyl groups is particularly preferred.

(ii) The epoxy compound includes a monomer, a dimer, an oligomer and a polymer containing at least one epoxy group. Examples of the epoxy compound include a reaction product of bisphenol A with epichlorohydrin and a reaction product of a low molecular weight phenol-formaldehyde resin with epichlorohydrin. Epoxy resins as described in U.S. Pat. No. 4,026,705 and British Patent 1,539,192 may also be used.

Photo-Acid Generator of Component (H) for Use in the Negative Resist Composition of the Present Invention

The photo-acid generator for use in the negative resist composition of the present invention can be appropriately selected from photoinitiators for photo-cationic polymerization, photoinitiators for photo-radical polymerization, photo-achromatic agents for dyes, photo-discoloring agents, compounds generating an acid with known light used for microresists (for example, an ultraviolet ray having a wavelength of from 400 to 200 or a far ultraviolet ray, particularly preferably g-line, h-line, i-line or a KrF excimer laser beam), an ArF excimer laser beam, an electron beam, an X ray, a molecular beam or an ion beam, and a mixture thereof.

Specific examples of the photo-acid generator for use in the present invention include onium salts, e.g., diazonium salts, ammonium salts, phosphonium salts, iodonium salts, sulfonium salts, selenonium salts or arsonium salts, organic halogen compounds, organic metal/organic halogen compounds, photo-acid generators having an o-nitrobenzyl protecting group, compounds generating a sulfonic acid by photolysis including typically iminosulfonates, disulfone compounds, diazoketosulfone compounds and diazodisulfone compounds.

It is also possible to use polymer compounds having, in the main chain or side chain thereof, a group or compound capable of generating an acid by irradiation of an active ray or radiation described above.

Further, compounds generating an acid by light as described, for example, in V. N. R. Pillai, Synthesis, (1), 1 (1980), A. Abad et al, Tetrahedron Lett., (47), 4555 (1971), D. H. R. Barton et al, J. Chem. Soc., (C), 329 (1970), U.S. Pat. No. 3,779,778 and European Patent 126,712 are also used.

Of the photo-acid generators of component (H), those particularly effectively used are described in detail below.

<A-1>: An oxazole derivative substituted with a trihalomethyl group represented by formula (PAG1) shown below or an S-triazine derivative substituted with a trihalomethyl group represented by formula (PAG2) shown below.

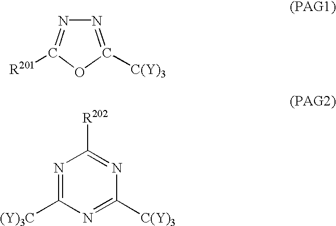

In the formulae, R²⁰¹ represents a substituted or unsubstituted aryl group or a substituted or unsubstituted alkenyl group; R²⁰² represents a substituted or unsubstituted aryl group, a substituted or unsubstituted alkenyl group, a substituted or unsubstituted alkyl group or —C(Y)₃; and Y represents a chlorine atom or a bromine atom.

Specific examples of the compound are set forth below, but the present invention should not be construed as being limited thereto.

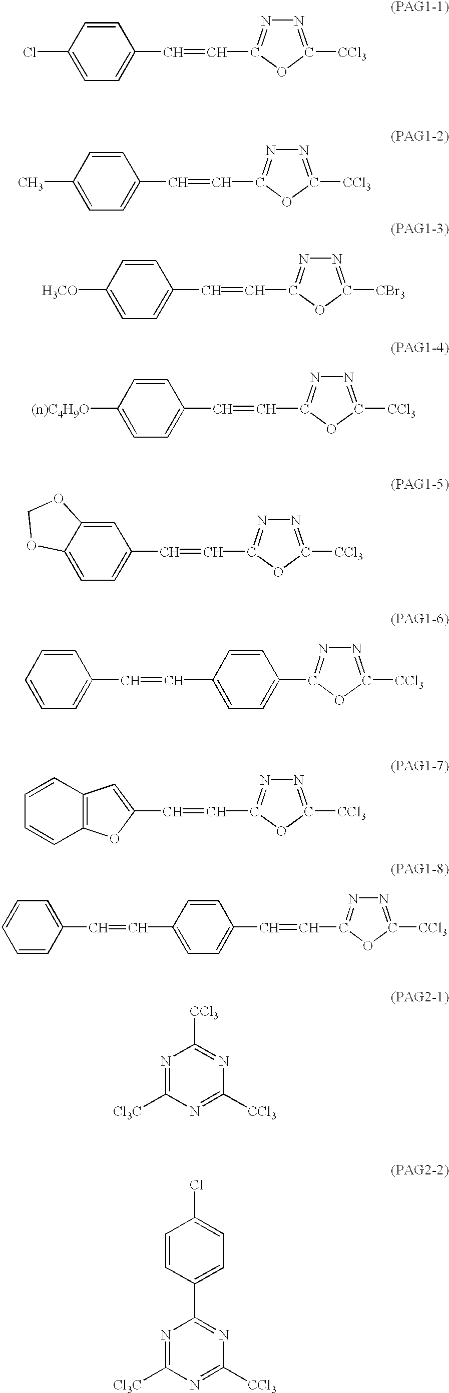

<A-2>: An Iodonium salt represented by formula (PAG3) shown below or a sulfonium salt represented by formula (PAG4) shown below.

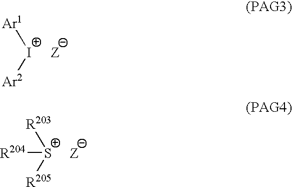

In the formulae, Ar¹ and Ar², which may be the same or different, each represent a substituted or unsubstituted aryl group.

R²⁰³, R²⁰⁴ and R²⁰⁵, which may be the same or different, each represent a substituted or unsubstituted alkyl or a substituted or unsubstituted aryl group.

Z⁻ represents a counter anion. Examples of the counter anion include BF₄⁻, AsF₆⁻, PF₆⁻, SbF₆⁻, SiF₆²—, ClO₄⁻, a perfluoroalkanesulfonic acid anion, e.g., CF₃SO₃⁻, an alkylsulfonic acid anion, e.g., camphenesulfonic acid anion, an aromatic sulfonic acid anion, e.g., pentafluorobenzenesulfonic acid anion, benzenesulfonic acid anion or triisopropylbenzenesulfonic acid anion, a condensed polycyclic aromatic sulfonic acid anion, e.g., naphthalene-1-sulfonic acid anion, an anthraquinone sulfonic acid anion and a dye containing a sulfonic acid, but the present invention should not be construed as being limited thereto. The anion moiety may further have a substituent.

Two of R²⁰³, R²⁰⁴ and R²⁰⁵, or Ar¹ and Ar² may be connected with each other through a single bond or a substituent.

Specific examples of the compound include (PAG3-1) to (PAG3-25) and (PAG4-1) to (PAG4-37) described hereinbefore, but the present invention should not be construed as being limited thereto.

The onium salts represented by formulae (PAG3) and (PAG4) are known and can be synthesized according to methods described, for example, in J. W. Knapczyk et al, J. Am. Chem. Soc., 91, 145 (1969), A. L. Maycok et al, J. Org. Chem., 35, 2532 (1970), E. Goethas et al, Bull. Soc. Chem. Belg., 73, 546 (1964), H. M. Leicester, J. Am. Chem. Soc., 51, 3587 (1929), J. V. Crivello et al, J. Polym. Chem. Ed., 18,-2677 (1980), U.S. Pat. Nos. 2,807,648 and 4,247,473 and JP-A-53-101,331.

<A-3>: A disulfone derivative represented by formula (PAG5) shown below and an iminosulfonate derivative represented by formula (PAG6) shown below.

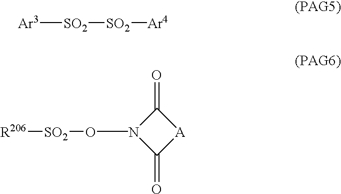

In the formulae, Ar³ and Ar⁴, which may be the same or different, each represent a substituted or unsubstituted aryl group. R²⁰⁶ represents a substituted or unsubstituted alkyl group or a substituted or unsubstituted aryl group. A represents a substituted or unsubstituted alkylene group, a substituted or unsubstituted alkenylene group or a substituted or unsubstituted arylene group.

Specific examples of the compound include (PAG5-1) to (PAG5-15) and (PAG6-1) to (PAG6-20) described hereinbefore, but the present invention should not be construed as being limited thereto.

<A-4>: A diazodisulfone derivative represented by formula (PAG7) shown below.

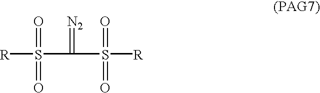

In the formula, R represents a straight chain, branched or cyclic alkyl group or an aryl group which may be substituted.

Specific examples of the compound include (PAG7-1) to (PAG7-5) described hereinbefore, but the present invention should not be construed as being limited thereto.

The photo-acid generator of component (H) is not an indispensable component in the negative resist composition of the present invention. However, it is preferred to use the photo-acid generator of component (H) together with the compound of component (C), since various properties, for example, sensitivity or resolution can be further improved.

The amount of the photo-acid generator of component (H) for use in the present invention is suitably from 0.1 to 30% by weight, preferably from 0.5 to 20% by weight, and more preferably from 1 to 15% by weight, based on the total solid content of the negative resist composition. When the amount of the photo-acid generator of component (H) is less than 0.1% by weight, the effect of increasing sensitivity is not achieved, and on the other hand, when the amount of the photo-acid generator of component (H) is more than 30% by weight, a resist profile is degraded due to the excessive light absorption and a film forming property is deteriorated.

The photo-acid generators of component (H) may be used individually or in combination of two or more thereof.

A weight ratio of the compound of component (C) to the photo-acid generator of component (H) is ordinarily from 100/0 to 5/95, preferably from 95/5 to 10/90, and particularly preferably from 90/10 to 20/80.

Other Components for Use in the Negative Resist Composition of the Present Invention

Into the negative resist composition of the present invention, other components, for example, a nitrogen-containing basic compound, a dye, a solvent, a surface active agent, a plasticizer, a photo-decomposable base compound or a photo-base generator may be incorporated, if desired.

The nitrogen-containing basic compound (Component (E)), dye, solvent and surface active agent are same as those described hereinbefore, respectively.

Plasticizer

The plasticizer for use in the negative resist composition of the present invention includes compounds as described in JP-A-4-212960, JP-A-8-262720, European Patents 735,422, 416,873 and 439,371, and U.S. Pat. No. 5,846,690. Specific examples thereof include di(2-ethylhexyl) adipate, n-hexyl benzoate, di-n-octyl phthalate, di-n-butyl phthalate, benzyl n-butyl phthalate and dihydroabietyl phthalate.

Photo-Decomposable Base Compound

The negative resist composition of the present invention may contain an ammonium salt as described in JP-A-7-28247, European Patent 616,258, U.S. Pat. No. 5,525,443, JP-A-9-127700, European Patent 762,207 and U.S. Pat. No. 5,783,354. Specific examples of the ammonium salt include tetramethylammonium hydroxide, tetra-n-butylammonium hydroxide and a betaine. Also, a compound (photo-base) which decreases basicity upon exposure to light as described in JP-A-5-232706, JP-A-6-11835, JP-A-6-242606, JP-A-6-266100, JP-A-7-333851, JP-A-7-333844, U.S. Pat. No. 5,663,035 and European Patent 677,788.

Photo-Base Generator

The photo-base generator for use in the negative resist composition of the present invention includes compounds as described in JP-A-4-151156, JP-A-4-162040, JP-A-5-197148, JP-A-5-5995, JP-A-6-194834, JP-A-8-146608, JP-A-10-83079 and European Patent 622,682. Specifically, 2-nitrobenzylcarbamate, 2,5-dinitrobenzylcyclohexylcarbamate, N-cyclohexyl-4-methylphenylsulfonamide or 1,1-dimethyl-2-phenylethyl-N-isopropylcarbamate is preferably used. The photo-base generator is used, for example, for the purpose of improving a resist profile.

The negative resist composition according to the present invention is coated on a substrate to form a thin film. A thickness of the coating film is preferably from 0.1 to 4.0 μm.

In the present invention, a known inorganic or organic reflection preventing coating may be used, if desired. Further, the reflection preventing coating may be applied to the resist layer. The reflection preventing coating described hereinbefore with respect to the positive resist composition is also used.

The pattern formation process on a resist film in the production of precision integrated circuit element comprises applying the negative resist composition of the present invention to a substrate (for example, a silicon/silicon dioxide film, a glass substrate or a metal substrate) directly or on the reflection preventing coating previously provided on the substrate, irradiating the coated film with an excimer laser beam, electron beam or X ray exposure device, heating, developing, rinsing and drying the coated film to form a good resist pattern. The exposure source used includes preferably light having a wavelength of from 150 to 250 nm (e.g., KrF excimer laser (248 nm), ArF excimer laser (193 nm) or F₂ excimer laser (157 nm)), an electron beam and an X ray. Particularly, a device using a KrF excimer laser, an electron beam or an X ray as the exposure source is preferred.

As a developer for the negative resist composition of the present invention, the developer described hereinbefore with respect to the positive resist composition is also used.

The present invention will be described in greater detail with reference to the following examples, however, the present invention should not be construed as being limited thereto.

### SYNTHESIS EXAMPLE 1

### Synthesis of Polymer (B-21)

In 120 ml of butyl acetate was dissolved 32.4 g (0.2 mol) of p-acetoxystyrene and 7.01 g (0.07 mol) of tert-butyl methacrylate. To the solution were added three times each 0.033 g of azobisisobutyronitrile (AIBN) at an interval of 2.5 hours at 80° C. with stirring in a nitrogen stream and then the mixture was further stirred for 5 hours, whereby the polymerization reaction was conducted. The resulting reaction solution was poured into 1,200 ml of hexane to precipitate a white resin. The resin obtained was dried and then dissolved in 200 ml of methanol.

To the solution was added an aqueous solution prepared by dissolving 7.7 g (0.19 mol) of sodium hydroxide in 50 ml of water, and the mixture was refluxed by heating for one hour to hydrolyze the resin. Then, the reaction mixture was diluted with 200 ml of water and neutralized with hydrochloric acid to deposit a white resin. The resin was collected by filtration, washed with water, dried, and then dissolved in 200 ml of tetrahydrofuran to prepare a solution. The solution was added dropwise to 5 liters of ultrapure water with vigorous stirring to reprecipitate. The reprecipitation operation was repeated three times. The resin thus obtained was dried in a vacuum dryer at 120° C. for 12 hours to obtain copoly(p-hydroxystyrene/tert-butyl methacrylate).

### SYNTHESIS EXAMPLE 2

### Synthesis of Polymer (B-3)

In 50 ml of pyridine was dissolved 10 g of poly(p-hydroxystyrene) (VP-8000, manufactured by Nippon Soda Co., Ltd.). To the solution was dropwise added 3.63 g of di-tert-butyl dicarbonate with stirring at room temperature. After stirring for 3 hours at room temperature, the reaction mixture was dropwise added to a solution containing 20 g of concentrated hydrochloric acid in one liter of ion-exchanged water. The powder thus deposited was collected by filtration, washed with water and dried to obtain Polymer (B-3).

SYNTHESIS EXAMPLE 3:

### Synthesis of Polymer (B-32)

In 300 ml of toluene was dissolved 83.1 g (0.5 mol) of p-cyclohexylphenol, and to the solution were added 150 g of 2-chloroethyl vinyl ether, 25 g of sodium hydroxide, 5 g of tetrabutylammonium bromide and 60 g of triethylamine, followed by reacting at 120° C. for 5 hours. The reaction solution was washed with water, and the excess 2-chloroethyl vinyl ether and toluene were distilled off. The oil thus obtained was purified by distillation under a reduced pressure to obtain 4-cyclohexylphenoxyethyl vinyl ether.

In 80 ml of tetrahydrofuran were dissolved 20 g of poly(p-hydroxystyrene) (VP-8000, manufactured by Nippon Soda Co., Ltd.) and 6.5 g of 4-cyclohexylphenoxyethyl vinyl ether. To the solution was dropwise added 0.01 g of p-toluenesulfonic acid, followed by reacting at room temperature for 18 hours. The reaction solution was added dropwise to 5 liters of distilled water with vigorous stirring, and the powder thus deposited was collected by filtration and dried to obtain Polymer (B-32).

Other polymers were synthesized in a similar manner. With the polymers for use in the following examples, the weight average molecular weight and the molar ratio of repeating unit are shown below.

| | Weight Average | Molar Ratio of |
|---|---|---|
| Polymer | Molecular Weight | Repeating unit* |
| (B-2) | 7,500 | 30/70 |
| (B-3) | 8,500 | 25/75 |
| (B-4) | 8,500 | 25/75 |
| (B-5) | 13,500 | 40/60 |
| (B-13) | 8,000 | 65/35 |
| (B-21) | 12,000 | 65/35 |
| (B-22) | 15,000 | 20/80 |
| (B-24) | 14,000 | 30/70 |
| (B-26) | 11,500 | 15/60/25 |
| (B-28) | 15,000 | 78/22 |
| (B-30) | 8,000 | 80/20 |
| (B-31) | 15,000 | 65/10/25 |
| (B-32) | 12,000 | 82/18 |
| (B-33) | 12,000 | 15/75/10 |

*The molar ratio of repeating unit is indicated using the repeating units of the polymers described in the specific examples of the polymer of component (B) hereinbefore and the numerals in each polymer mean the molar ratio of the repeating unit in order from left to right.

### EXAMPLE 1

(1) Preparation of Resist Film

In 8.5 g of propylene glycol monomethyl ether acetate were dissolved 0.05 g of Acid-generator (1-1) of component (A) and 0.94 g of Polymer (B-21) of component (B), and to the solution were added to dissolve 0.1 g of N-phenylbis(trifluoromethanesulfonimide) manufactured by Tokyo Kasei Kogyo Co., Ltd. (Compound (CC-3) of component (C)), 0.005 g of 1,5-diazabicyclo[4.3.0]-5-nonene (hereinafter referred to as Compound D-1) as the nitrogen-containing basic compound of component (E) and 0.001 g of Megafac F176 manufactured by Dainippon Ink and Chemicals Inc. (hereinafter referred to as Compound W-1) as a surface active agent. The resulting solution was subjected to microfiltration using a membrane filter having a pore size of 0.1 μm to prepare a resist solution.

The resist solution was coated on a 6-inch silicon wafer using a spin coater (Mark 8 manufactured by Tokyo Electron Ltd.) and baked at 110° C. for 90 seconds to prepare a uniform resist film having a thickness of 0.30 μm.

(2) Preparation and Evaluation of Resist Pattern

The resist film was subjected to electron beam irradiation using an electron beam imaging device (HL 750 manufactured by Hitachi, Ltd.; acceleration voltage: 50 KeV). After the irradiation, the resist film was baked at 110° C. for 90 seconds, immersed in a 2.38% by weight aqueous solution of tetramethylammonium hydroxide (TMAH) for 60 seconds to develop, rinsed with water for 30 seconds and dried. The pattern thus obtained was evaluated in the following manner.

(2-1) Sensitivity

A cross-sectional shape of the pattern was observed using a scanning electron microscope. The minimum irradiation energy necessary for resolving 0.20 μm-line (line:space=1:1) was designated as the sensitivity.

(2-2) Resolution

The resolution was expressed using a limiting resolution (line and space being separately resolved) at the irradiation amount sufficient for obtaining the above sensitivity.

(2-3) Pattern Profile

A cross-sectional shape of 0.14 μm-line pattern at the irradiation amount sufficient for obtaining the above sensitivity was observed using a scanning electron microscope and classified into three levels: rectangle, slight taper and taper, for the evaluation.

(2-4) Edge Roughness

A distance from the standard line where the edge should be present to the edge of the line pattern was measured in 30 points in the area of a length of 5 μm of the line pattern using a CD-SEM (S-8840, manufactured by Hitachi, Ltd.), standard deviation was determined and 3σ was calculated. The smaller the value, the better the quality.

The results of evaluation in Example 1 were good. Specifically, the sensitivity was 8.0° C./cm², the resolution was 0.10 μm, the pattern profile was rectangular, and the edge roughness was 9.5 nm.

### EXAMPLE 2

The preparation of resist film and preparation and evaluation of resist pattern were conducted in the same manner as in Example 1 except for using N-(2-pyridyl)-bis(trifluoromethanesulfonimide) manufactured by Tokyo Kasei Kogyo Co., Ltd. (Compound (CC-4) of component (C)) in place of Compound (CC-3) of component (C) used in Example 1. The results of evaluation are shown in Table 2 below.

### EXAMPLES 3 TO 10

The preparation of resist film and preparation and evaluation of resist pattern using the electron beam exposure were conducted in the same manner as in Example 1 except for using the compounds shown in Table 1 below. The results of evaluation are shown in Table 2 below.

### COMPARATIVE EXAMPLE 1

The preparation of resist film and preparation and evaluation of resist pattern using the electron beam exposure were conducted in the same manner as in Example 1 except for eliminating Compound (CC-3) of component (C). The results of evaluation are shown in Table 2 below.

### COMPARATIVE EXAMPLES 2 AND 3

The preparation of resist film and preparation and evaluation of resist pattern using the electron beam exposure were conducted in the same manner as in Example 1 except for using p-toluenesulfonamide (hereinafter referred to as C—A) and succinimide (hereinafter referred to as C-B), respectively, in place of Compound (CC-3) of component (C) used in Example 1. The results of evaluation are shown in Table 2 below.

Other compounds used in the examples are shown below.

Nitrogen-containing basic compound (D-2):

2-Phenylbenzimidazole

Nitrogen-containing basic compound (D-3):

Dicyclohexylmethylamine

Surface active agent (W-2):

Polysiloxane polymer KP341 (manufactured by Shin-Etu Chemical Co., Ltd.)

TABLE 1

| | | | | Nitrogen- | Surface |
|---|---|---|---|---|---|
| | Component | Component | Component | Containing | Active |
| Example | A | B | C | Compound | Agent |
| Example 1 | I-1 | B-21 | CC-3 | D-1 | W-1 |
| Example 2 | I-1 | B-21 | CC-4 | D-1 | W-1 |
| Example 3 | I-7 | B-3 | CC-3 | D-1 | — |
| Example 4 | I-8 | B-32 | CC-3 | D-2 | — |
| Example 5 | I-9 | B-4 | CC-3 | D-3 | W-2 |
| Example 6 | II-1 | B-28 | CC-4 | D-3 | W-2 |
| Example 7 | I-5 | B-30 | CC-4 | D-2 | W-2 |
| Example 8 | II-2 | B-30 | CC-4 | D-1 | W-1 |
| Example 9 | III-1 | B-4 | CC-5 | D-1 | W-1 |
| Example 10 | III-2 | B-3 | CC-11 | D-1 | W-1 |
| Comparative | I-1 | B-21 | — | D-1 | W-1 |
| Example 1 | | | | | |
| Comparative | I-1 | B-21 | C-A | D-1 | W-1 |
| Example 2 | | | | | |
| Comparative | I-1 | B-21 | C-B | D-1 | W-1 |
| Example 3 | | | | | |

TABLE 2

| | | | | Edge |
|---|---|---|---|---|
| | Sensitivity | Resolution | Pattern | Roughness |
| Example | (μC/cm²) | (μm) | Profile | (nm) |
| Example 1 | 8.0 | 0.10 | Rectangle | 9.5 |
| Example 2 | 7.5 | 0.09 | Rectangle | 8.4 |
| Example 3 | 7.0 | 0.10 | Slight Taper | 7.8 |
| Example 4 | 8.5 | 0.10 | Rectangle | 8.5 |
| Example 5 | 7.5 | 0.09 | Rectangle | 7.3 |
| Example 6 | 7.0 | 0.09 | Rectangle | 10.1 |
| Example 7 | 8.0 | 0.10 | Rectangle | 9.2 |
| Example 8 | 8.5 | 0.10 | Slight Taper | 8.3 |
| Example 9 | 8.0 | 0.10 | Rectangle | 9.0 |
| Example 10 | 7.5 | 0.09 | Rectangle | 9.8 |
| Comparative | 15.0 | 0.13 | Taper | 20.5 |
| Example 1 | | | | |
| Comparative | 9.5 | 0.13 | Slight Taper | 14.0 |
| Example 2 | | | | |
| Comparative | 12.0 | 0.11 | Taper | 15.5 |
| Example 3 | | | | |

As is apparent from the results shown in Table 2, the positive resist compositions containing the specific sulfonimide structure of component (C) have the high sensitivity and high resolution and are excellent in the pattern profile and edge roughness in comparison with the resist composition of comparative example not containing the compound of component (C) and the resist compositions of comparative examples containing other amide compounds having skeleton structures different from the compound of component (C) in case of conducting the electron beam irradiation.

### EXAMPLE 11

(1) Preparation of Resist Film

In 8.5 g of propylene glycol monomethyl ether acetate were dissolved 0.05 g of PAG3-1 of component (A) and 0.94 g of Polymer (B-22) of component (B), and to the solution were added to dissolve 0.07 g of Compound (CC-6) of component (C), 0.005 g of Compound D-1 as the nitrogen-containing basic compound of component (E) and 0.001 g of Compound W-1 as a surface active agent. The resulting solution was subjected to microfiltration using a membrane filter having a pore size of 0.1 μm to prepare a resist solution.

The resist solution was coated and baked in the same manner as in Example 1 to prepare a uniform resist film having a thickness of 0.30 μm.

(2) Preparation and Evaluation of Resist Pattern

The resist film was subjected to pattern exposure using a KrF excimer stepper (FPA3000EX-5 manufactured by Canon Inc.; wavelength: 248 nm). The processing after the exposure and evaluation of pattern were performed in the same manner as in Example 1.

The results of evaluation in Example 11 were good. Specifically, the sensitivity was 28 mJ/cm², the resolution was 0.13 μm, the pattern profile was rectangular, and the edge roughness was 7.0 nm.

### EXAMPLES 12 TO 18

The preparation of resist film and preparation and evaluation of resist pattern using the KrF excimer stepper were conducted in-the same manner as in Example 11 except for using the compounds shown in Table 3 below. The results of evaluation are shown in Table 4 below.

### COMPARATIVE EXAMPLE 4

The preparation of resist film and preparation and evaluation of resist pattern using the KrF excimer stepper were conducted in the same manner as in Example 11 except for eliminating Compound (CC-6) of component (C). The results of evaluation are shown in Table 4 below.

TABLE 3

| | | | | Nitrogen- | Surface |
|---|---|---|---|---|---|
| | Component | Component | Component | Containing | Active |
| Example | A | B | C | Compound | Agent |
| Example 11 | PAG3-1 | B-22 | CC-6 | D-1 | W-1 |
| Example 12 | PAG3-18 | B-2 | CC-14 | D-1 | W-1 |
| Example 13 | PAG4-4 | B-4 | CC-15 | D-1 | W-1 |
| Example 14 | PAG4-26 | B-21 | CC-16 | D-2 | W-1 |
| Example 15 | PAG5-13 | B-26 | CC-11 | D-3 | W-2 |
| Example 16 | PAG6-4 | B-28 | CC-17 | D-3 | W-2 |
| Example 17 | PAG6-12 | B-32 | CC-2 | D-2 | W-1 |
| Example 18 | PAG7-1 | B-32 | CC-6 | D-1 | W-1 |
| Comparative | PAG3-1 | B-22 | — | D-1 | W-1 |
| Example 4 | | | | | |

TABLE 4

| | | | | Edge |
|---|---|---|---|---|
| | Sensitivity | Resolution | Pattern | Roughness |
| Example | (mJ/cm²) | (μm) | Profile | (nm) |
| Example 11 | 28 | 0.13 | Rectangle | 7.0 |
| Example 12 | 30 | 0.13 | Rectangle | 6.5 |
| Example 13 | 26 | 0.13 | Rectangle | 8.0 |
| Example 14 | 29 | 0.14 | Rectangle | 8.0 |
| Example 15 | 33 | 0.13 | Rectangle | 9.5 |
| Example 16 | 30 | 0.14 | Rectangle | 6.5 |
| Example 17 | 30 | 0.13 | Slight Taper | 7.0 |
| Example 18 | 28 | 0.13 | Rectangle | 7.5 |
| Comparative | 38 | 0.15 | Taper | 18.5 |
| Example 4 | | | | |

### EXAMPLE 19

(1) Preparation of Resist Film

In 8.5 g of propylene glycol monomethyl ether were dissolved 0.93 g of Polymer (B-4) of component (B) and 0.08 g Compound (CC-6) of component (C), and to the solution were added to dissolve 0.003 g of Compound D-1 as the nitrogen-containing basic compound of component (E) and 0.001 g of Compound W-1 as a surface active agent. The resulting solution was subjected to microfiltration using a membrane filter having a pore size of 0.1 μm to prepare a resist solution.

The resist solution was coated and baked in the same manner as in Example 1 to prepare a uniform resist film having a thickness of 0.30 μm.

The preparation and evaluation of resist pattern were conducted in the same manner as in Example 11.

The results of evaluation in Example 19 were good. Specifically, the sensitivity was 35 mJ/cm², the resolution was 0.14 μm, the pattern profile was rectangular, and the edge roughness was 9.0 nm.

### EXAMPLES 20 TO 24

The preparation of resist film and preparation and evaluation of resist pattern using the KrF excimer stepper were conducted in the same manner as in Example 11 except for using the compounds shown in Table 5 below. The results of evaluation are shown in Table 6 below.

### COMPARATIVE EXAMPLE 5

The preparation of resist film and preparation and evaluation of resist pattern using the KrF excimer stepper were conducted in the same manner as in Example 11 except for using each of the compounds of component (A) in place of Compound (CC-6) of component (C) used in Example 19. The results of evaluation are shown in Table 6 below.

TABLE 5

| | | | | Nitrogen- | Surface |
|---|---|---|---|---|---|
| | Component | Component | Component | Containing | Active |
| Example | A | B | C | Compound | Agent |
| Example 19 | — | B-4 | CC-6 | D-1 | W-1 |
| Example 20 | — | B-5 | CC-11 | D-1 | W-1 |
| Example 21 | — | B-13 | CC-2 | D-1 | W-1 |
| Example 22 | — | B-22 | CC-14 | D-3 | W-1 |
| Example 23 | — | B-24 | CC-6 | D-2 | W-1 |
| Example 24 | — | B-31 | CC-3 | D-1 | W-1 |
| Comparative | PAG3-1 | B-4 | — | D-1 | W-1 |
| Example 5 | | | | | |

TABLE 6

| | | | | Edge |
|---|---|---|---|---|
| | Sensitivity | Resolution | Pattern | Roughness |
| Example | (mJ/cm²) | (μm) | Profile | (nm) |
| Example 19 | 33 | 0.14 | Rectangle | 9.0 |
| Example 20 | 35 | 0.13 | Rectangle | 9.0 |
| Example 21 | 30 | 0.14 | Rectangle | 9.5 |
| Example 22 | 29 | 0.13 | Slight Taper | 7.5 |
| Example 23 | 36 | 0.13 | Slight Taper | 9.0 |
| Example 24 | 30 | 0.14 | Rectangle | 10.5 |
| Comparative | 34 | 0.16 | Taper | 20.5 |
| Example 5 | | | | |

As described above, it can be seen that the positive resist compositions of the present invention exhibit the excellent properties not only in case of the electron beam exposure but also in case of the KrF excimer laser beam exposure.

According to the present invention, the positive resist composition excellent not only in the sensitivity and resolution but also in the pattern profile and edge roughness can be provided.

### SYNTHESIS EXAMPLE 4

### Synthesis of Polymer (29)

In 30 ml of 1-methoxy-2-propanol were dissolved 3.9 g (0.024 mol) of 4-acetoxystyrene and 0.8 g (0.006 mol) of 4-methoxystyrene, and while stirring the solution under a nitrogen gas stream, 70 ml of a 1-methoxy-2-propanol solution of 50 mg of a polymerization initiator, i.e., 2,2′-azobis(2,4-dimethylvaleronitrile) (V-65, manufactured by Wako Pure Chemical Industries, Ltd.), 9.1 g (0.056 mol) of 4-acetoxystyrene, and 1.9 g (0.014 mol) of 4-methoxystyrene was added dropwise thereto at 70° C. over a period of 2 hours. After 2 hours, 50 mg of the initiator was additionally added thereto and the reaction was further continued for 2 hours. Thereafter, the temperature was raised to 90° C. and the reaction mixture was stirred for one hour. After cooling of the reaction solution, a white resin was deposited by pouring the reaction liquid into one liter of ion-exchanged water with vigorous stirring. The resulting resin was dried, and then dissolved in 100 ml of methanol, and 25% tetramethylammonium hydroxide was added thereto to hydrolyze the acetoxy group in the resin. Then, the solution was neutralized with an aqueous solution of hydrochloric acid to deposite a white resin. The resin was washed with ion-exchanged water and dried under a reduced pressure to obtain 11.6 g of Polymer (29) of the present invention. A molecular weight of the polymer was measured by GPC, and the weight average molecular weight in terms of polystyrene (Mw) was 9,200 and the degree of dispersion (Mw/Mn) was 2.2.

Other resins of component (F) of the present invention were synthesized in a similar manner.

### SYNTHESIS EXAMPLE 5

### Synthesis of Acid Generator (PAG4-7)

1) Synthesis of Tetramethylammonium Pentafluorobenzenesulfonate

In 100 ml of methanol was dissolved 25 g of pentafluorobenzenesulfonyl chloride under cooling with ice, and 100 g of a 25% aqueous solution of tetramethylammonium hydroxide was slowly added thereto. The mixture was stirred for 3 hours at room temperature to obtain a solution of tetramethylammonium pentafluorobenzenesulfonate. The solution was used for salt-exchange with a sulfonium salt or an iodonium salt.

2) Synthesis of Triphenylsulfonium Pentafluorobenzene Sulfonate

In 800 ml of benzene was dissolved 50 g of diphenyl sulfoxide, to the solution was added 200 g of aluminum chloride, and the mixture was refluxed for 24 hours. The reaction solution was slowly poured into 2 liters of ice water, and after the addition of 400 ml of concentrated hydrochloric acid, the mixture was heated at 70° C. for 10 minutes. The aqueous solution was washed with 500 ml of ethyl acetate, and after filtration, a solution of 200 g of ammonium iodide dissolved in 400 ml of water was added. The powder thus deposited was collected by filtration, washed with water and then with ethyl acetate, and dried to obtain 70 g of triphenylsulfonium iodide.

In 1000 ml of methanol was dissolved 30.5 g of triphenylsulfonium iodide, and after the addition of 19.1 g of silver oxide to the solution, the mixture was stirred at room temperature for 4 hours. The solution was filtered and to the filtrate was added an excessive amount of the solution of tetramethylammonium pentafluorobenzenesulfonate described above. The reaction solution was concentrated, the residue was dissolved in 500 ml of dichloromethane, and the solution was washed with a 5% aqueous solution of tetramethylammonium hydroxide and then with water. The organic phase was dried over anhydrous sodium sulfate, and then, concentrated to obtain triphenylsulfonium pentafluorobenzenesulfonate (PAG4-7).

### SYNTHESIS EXAMPLE 6

### Synthesis of Di(4-tert-amylphenyl)iodonium Pentafluorobenzenesulfonate (Acid Generator (PAG3-22))

Sixty grams of tert-amylbenzene, 39.5 g of potassium iodate, 81 g of acetic anhydride and 170 ml of dichloromethane were mixed, and 66.8 g of concentrated sulfuric acid was slowly added dropwise to the mixture under cooling with ice. After stirring under cooling with ice for 2 hours, the mixture was further stirred at room temperature for 10 hours. To the reaction solution was added 500 ml of water under cooling with ice, and the resulting mixture was extracted with dichloromethane. The organic phase was washed with sodium hydrogen carbonate and then with water, and concentrated to obtain di(4-tert-amylphenyl)iodonium sulfate. The resulting sulfate was added to an excessive amount of the solution of tetramethylammonium pentafluorobenzenesulfonate described above. To the solution was added 500 ml of water, and the solution was extracted with dichloromethane. The organic phase was washed with a 5% aqueous solution of tetramethylammonium hydroxide and then with water, and concentrated to obtain di(4-tert-amylphenyl)iodonium pentafluorobenzenesulfonate (PAG3-22).

Other acid generator compounds of the present invention were synthesized in a similar manner.

### SYNTHESIS EXAMPLE 7

### Synthesis of Crosslinking Agent (HM-1)

To a 10% aqueous solution of potassium hydroxide was added to dissolve 20 g of 1-[α-methyl-α-(4-hydroxyphenyl)ethyl]-4-[α,α-bis(4-hydroxyphenyl)ethyl]-benzene (Trisp-PA, manufactured by Honshu Chemical Industry Co., Ltd.) with stirring. While stirring the solution, 60 ml of a 37% aqueous formalin solution was gradually added thereto at room temperature over a period of 1 hour. After further stirring at room temperature for 6 hours, the solution was poured into a diluted aqueous sulfuric acid solution. The precipitates thus formed were collected by filtration, sufficiently washed with water, and recrystallized from 30 ml of methanol to obtain 20 g of white powder of phenol derivative (Crosslinking Agent (HM-1)) containing hydroxymethyl groups having the structure shown below. The purity thereof was 92% (determined by a liquid chromatography method).

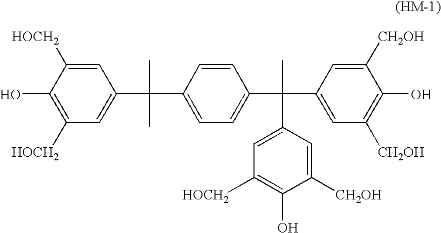

### SYNTHESIS EXAMPLE 8

### Synthesis of Crosslinking Agent (MM-1)

To one liter of methanol was added to dissolve 20 g of the phenol derivative (Crosslinking Agent (HM-1)) having hydroxymethyl groups obtained above with heating and stirring. To the solution was added 1 ml of concentrated sulfuric acid, and the mixture was refluxed for 12 hours. After the completion of the reaction, the reaction solution was cooled and 2 g of potassium carbonate was added thereto. The mixture was sufficiently concentrated, and 300 ml of ethyl acetate was added thereto. The solution was washed with water and concentrated to dryness to obtained 22 g of phenol derivative (Crosslinking Agent (MM-1)) containing methoxymethyl groups having the structure shown below as a white solid. The purity thereof was 90% (determind by a liquid chromatography method).

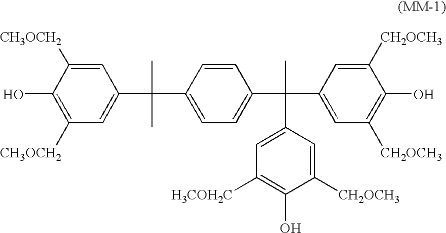

Furthermore, the phenol derivatives shown below were synthesized in a similar manner.

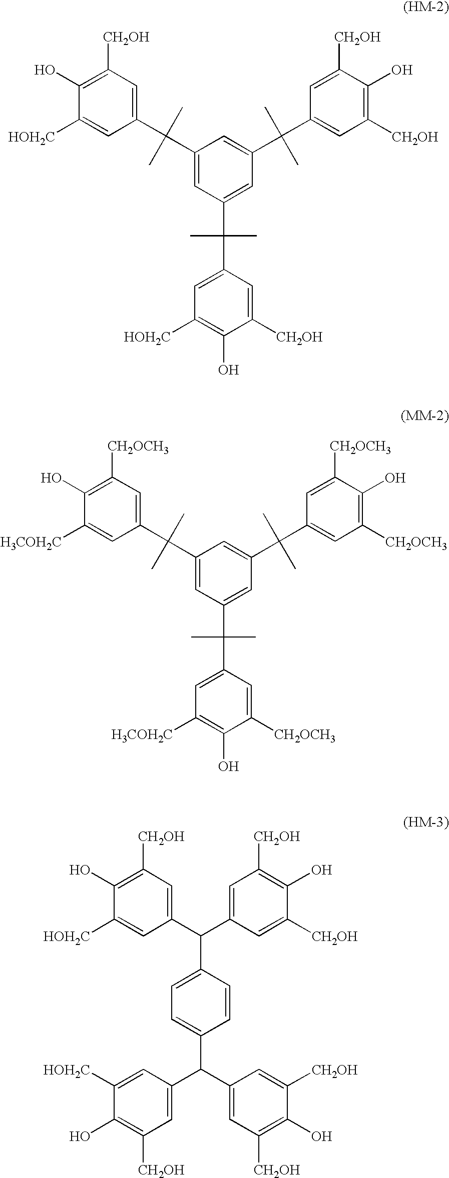

### EXAMPLE 101

(1) Preparation of Negative Resist Film

In 8.5 g of propylene glycol monomethyl ether acetate were dissolved 0.80 g of Polymer (1) of component (F), 0.25 g of Crosslinking Agent (MM-1) of component (G) and 0.05 g of Acid Generator (PAG4-7) of component (H), and to the solution were added to dissolve 0.05 g of N-phenylbis(trifluoromethanesulfonimide) manufactured by Tokyo Kasei Kogyo Co., Ltd. (Compound (CC-3) of component (C)), 0.002 g of OE-1 as the nitrogen-containing basic compound of component (E) and 0.001 g of Megafac F176 manufactured by Dainippon Ink and Chemicals Inc. (hereinafter referred to as Compound W-1) as a surface active agent. The resulting solution was subjected to microfiltration using a membrane filter having a pore size of 0.1 μm to prepare a resist solution.

The resist solution was coated on a 6-inch silicon wafer using a spin coater (Mark 8 manufactured by Tokyo Electron Ltd.) and dried at 110° C. for 90 seconds on a hot plate to prepare a resist film having a thickness of 0.3 μm.

(2) Preparation and Evaluation of Negative Resist Pattern

The resist film was subjected to pattern exposure using a KrF excimer stepper (FPA3000EX-5 manufactured by Canon Inc.; wavelength: 248 nm; NA: 0.63). After the exposure, the resist film was heated at 110° C. for 90 seconds on a hot plate, immersed in a 2.38% by weight aqueous solution of tetramethylammonium hydroxide (TMAH) for 60 seconds to develop, rinsed with water for 30 seconds and dried. The pattern thus obtained was evaluated in the following manner.

(2-1) Sensitivity

A cross-sectional shape of the pattern was observed using a scanning electron microscope (S-4300, manufactured by Hitachi, Ltd.). The minimum exposure amount necessary for resolving 0.16 μm-line (line:space=1:1) was designated as the sensitivity.

(2-2) Resolution

The resolution was expressed using a limiting resolution (line and space being separately resolved) at the exposure amount sufficient for obtaining the above sensitivity.

(2-3) Pattern Profile

A cross-sectional shape of 0.16 μm-line pattern at the irradiation amount sufficient for obtaining the above sensitivity was observed using a scanning electron microscope (S-4300, manufactured by Hitachi, Ltd.) and classified into three levels: rectangle, slight taper and taper, for the evaluation.

(2-4) Line Edge Roughness

A distance from the standard line where the edge should be present to the edge of the 0.16 μm-line pattern at the exposure amount sufficient for obtaining the above sensitivity was measured in 50 points in the area of a length of 5 μm of the line pattern using a CD-SEM (S-8840, manufactured by Hitachi, Ltd.), standard deviation was determined and 3σ was calculated. The smaller the value, the better the quality.

The results of evaluation in Example 101 were good. Specifically, the sensitivity was 25 mJ/cm², the resolution was 0.13 μm, the pattern profile was rectangular, and the edge roughness was 5.0 nm.

### EXAMPLES 102 TO 110

The preparation of resist film and preparation and evaluation of negative resist pattern were conducted in the same manner as in Example 101 except for using the components shown in Table 101 below. The results of evaluation are shown in Table 102 below.

### COMPARATIVE EXAMPLE 101

The preparation of resist film and preparation and evaluation of negative resist pattern were conducted in the same manner as in Example 101 except for eliminating the sulfonimide compound of component (C). The results of evaluation are shown in Table 102 below.

### COMPARATIVE EXAMPLE 102

The preparation of resist film and preparation and evaluation of negative resist pattern using the electron beam exposure were conducted in the same manner as in Example 103 except for using succinimide (manufactured by Tokyo Kasei Kogyo Co., Ltd.) (hereinafter referred to as C-B) in place of the sulfonimide compound of component (C) used in Example 103. The results of evaluation are shown in Table 102 below.

TABLE 101

| | | Acid | Cross- | Sulfonimide | Nitrogen- | Surface |
|---|---|---|---|---|---|---|
| | | Generator | linking | Compound | Containing | Active |
| | Resin (F) | (H) | Agent | (C) | Basic | Agent |
| Example | (0.80 g) | (0.05 g) | (G) | (0.05 g) | Compound (E) | (0.001 g) |
| Example 101 | (1) | PAG4-7 | MM-1 | CC-3 | OE-1 | W-1 |
| | Mw = 8,000 | | 0.25 g | | 0.002 g | |
| | Mw/Mn = 1.5 | | | | | |
| Example 102 | (2) | PAG4-36 | MM-2 | CC-4 | OE-1 | W-1 |
| | Mw = 11,000 | | 0.20 g | | 0.002 g | |
| | Mw/Mn = 1.4 | | | | | |
| Example 103 | (27) | PAG4-7 | MM-1 | CC-3 | OE-1 | W-1 |
| | Mw = 7,500 | | 0.20 g | | 0.002 g | |
| | X/y = 80/20 | | | | | |
| | Mw/Mn = 1.7 | | | | | |
| Example 104 | (29) | PAG3-22 | MM-1 | CC-3 | OE-2 | W-1 |
| | Mw = 9,200 | | 0.20 g | | 0.002 g | |
| | X/y = 80/20 | | | | | |
| | Mw/Mn = 2.2 | | | | | |
| Example 105 | (93) | PAG4-26 | MM-1 | CC-3 | OE-3 | — |
| | Mw = 9,000 | | 0.20 g | | 0.002 g | |
| | X/y = 85/15 | | | | | |
| | Mw/Mn = 1.6 | | | | | |
| Example 106 | (94) | PAG4-36 | MM-3 | CC-3 | OE-3 | W-2 |
| | Mw = 12,000 | | 0.20 g | | 0.002 g | |
| | X/y = 90/10 | | | | | |
| | Mw/Mn = 2.0 | | | | | |
| Example 107 | (96) | PAG5-1 | MM-4 | CC-4 | OE-1 | W-2 |
| | Mw = 7,000 | | 0.25 g | | 0.002 g | |
| | X/y = 90/10 | | | | | |
| | Mw/Mn = 2.2 | | | | | |
| Example 108 | (15) | PAG4-24 | MM-5 | CC-5 | OE-1 | W-1 |
| | Mw = 12,800 | | 0.25 g | | 0.002 g | |
| | Mw/Mn = 1.8 | | | | | |
| Example 109 | (1) | PAG3-23 | CL-1 | CC-11 | OE-4 | — |
| | Mw = 15,000 | | 0.20 g | | 0.002 g | |
| | Mw/Mn = 1.4 | | | | | |
| Example 110 | (2) | PAG7-1 | CL-2 | CC-3 | OE-4 | W-1 |
| | Mw = 24,000 | | 0.20 g | | 0.002 g | |
| | Mw/Mn = 1.6 | | | | | |
| Comparative | (1) | PAG4-7 | MM-1 | — | OE-1 | W-1 |
| Example 101 | Mw = 8,000 | | 0.20 g | | 0.002 g | |
| | Mw/Mn = 1.5 | | | | | |
| Comparative | (27) | PAG4-7 | MM-1 | C-B | OE-1 | W-1 |
| Example 102 | Mw = 7,500 | | 0.20 g | | 0.002 g | |
| | X/y = 80/20 | | | | | |
| | Mw/Mn = 1.7 | | | | | |

Explanation of the abbreviations in Table 101:

Crosslinking Agent CL-1:

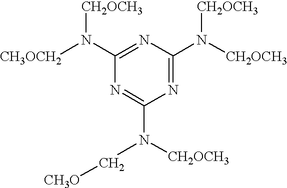

Crosslinking Agent CL-2:

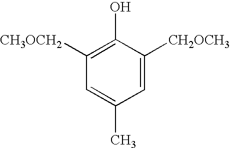

OE-1: 4-Dimethylaminopyridine

OE-2: Benzimidazole

OE-3: 2,4,5-Triphenylimidazole

OE-4: 1,4-Diazabicyclo[5.4.0]undecene

W-2: Siloxane polymer KP341 (manufactured by Shin-Etsu Chemical Co., Ltd.)

TABLE 102

| | | | Pattern | Line |
|---|---|---|---|---|
| | | | Profile | Edge |
| | Sensitivity | Resolution | (Three-Level | Roughness |
| Example | (mJ/cm²) | (μm) | Evaluation) | (nm) |
| Example 101 | 25 | 0.13 | Rectangle | 5.0 |
| Example 102 | 28 | 0.14 | Rectangle | 6.5 |
| Example 103 | 30 | 0.13 | Rectangle | 7.0 |
| Example 104 | 31 | 0.13 | Rectangle | 7.5 |
| Example 105 | 28 | 0.13 | Rectangle | 6.0 |
| Example 106 | 25 | 0.14 | Slight Taper | 7.5 |
| Example 107 | 28 | 0.14 | Rectangle | 7.0 |
| Example 108 | 30 | 0.13 | Rectangle | 8.5 |
| Example 109 | 35 | 0.14 | Slight Taper | 6.0 |
| Example 110 | 34 | 0.13 | Rectangle | 8.5 |
| Comparative | 30 | 0.16 | Taper | 23.0 |
| Example 101 | | | | |
| Comparative | 46 | 0.16 | Slight Taper | 21.0 |
| Example 102 | | | | |

### EXAMPLES 111 TO 120

(1) Preparation of Resist Film

The preparation, coating and drying of resist composition solutions were conducted in the same manner as in Example 101 to 110, thereby preparing resist films each having a thickness of 0.3 μm.

(2) Preparation and Evaluation of Negative Resist Pattern

The resist film was subjected to electron beam irradiation using an electron beam imaging device (HL 750 manufactured by Hitachi, Ltd.; acceleration voltage: 50 KeV). After the irradiation, the resist film was heated at 110° C. for 90 seconds on a hot plate, immersed in a 2.38% by weight aqueous solution of tetramethylammonium hydroxide (TMAH) for 60 seconds to develop, rinsed with water for 30 seconds and dried. The pattern thus obtained was evaluated in the same manner in Example 101.

The results of evaluation in Example 111 were good. Specifically, the sensitivity was 8.5 μC/cm², the resolution was 0.10 μm, the pattern profile was rectangular, and the line edge roughness was 6.5 nm.

The results of evaluation with Examples 112 to 120 are shown in Table 103 below.

### COMPARATIVE EXAMPLES 103 AND 104

The preparation of resist film was conducted in the same manner as in Comparative Examples 101 and 102, respectively, and the electron beam irradiation was performed in the same manner as in Example 111, thereby forming negative resist patterns. The evaluation was conducted in the same manner as in Example 111. The results of evaluation are shown in Table 103 below.

TABLE 103

| | | | Pattern | Line |
|---|---|---|---|---|
| | | | Profile | Edge |
| | Sensitivity | Resolution | (Three-Level | Roughness |
| Example | (μC/cm²) | (μm) | Evaluation) | (nm) |
| Example 111 | 8.5 | 0.10 | Rectangle | 6.5 |
| Example 112 | 7.5 | 0.11 | Rectangle | 7.0 |
| Example 113 | 8.0 | 0.10 | Rectangle | 5.0 |
| Example 114 | 8.0 | 0.09 | Rectangle | 6.0 |
| Example 115 | 9.0 | 0.10 | Rectangle | 6.0 |
| Example 116 | 7.5 | 0.10 | Rectangle | 7.5 |
| Example 117 | 8.0 | 0.11 | Rectangle | 6.5 |
| Example 118 | 9.0 | 0.09 | Slight Taper | 6.5 |
| Example 119 | 7.5 | 0.10 | Rectangle | 6.0 |
| Example 120 | 8.0 | 0.10 | Rectangle | 5.5 |
| Comparative | 9.0 | 0.14 | Slight Taper | 18.5 |
| Example 103 | | | | |
| Comparative | 13.5 | 0.13 | Slight Taper | 17.0 |
| Example 104 | | | | |

From the results shown in Tables 102 and 103, it is apparent that the negative resist compositions of the present invention are excellent in the sensitivity and resolution as well as in the pattern profile and line edge roughness not only in case of the KrF excimer laser beam exposure but also in case of the electron beam exposure.

According to the present invention, the negative resist composition excellent not only in the sensitivity and resolution but also in the pattern profile and line edge roughness can be provided.

The entire disclosure of each and every foreign patent application from which the benefit of foreign priority has been claimed in the present application is incorporated herein by reference, as if fully set forth herein.

While the invention has been described in detail and with reference to specific examples thereof, it will be apparent to one skilled in the art that various changes and modifications can be made therein without departing from the spirit and scope thereof.

What is claimed is:

1. A resist composition comprising (C) a compound having a sulfonimide structure represented by the following formula (I): 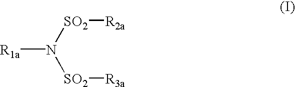
wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or an aromatic group containing a hetero atom, which may have a substituent.

2. A positive resist composition comprising (B) a polymer which is insoluble or hardly soluble in an aqueous alkali solution but becomes soluble in the aqueous alkali solution by the action of an acid, and (C) a compound having a sulfonimide structure represented by the following formula (I): 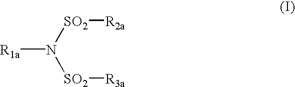
wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or a heterocyclic group which may have a substituent.

3. The positive resist composition as claimed in claim 2 further comprising (A) a compound which generates an acid by irradiation of an active ray or radiation other than the compound (C).

4. The positive resist composition as claimed in claim 2 further comprising (E) a nitrogen-containing basic compound.

5. The positive resist composition as claimed in claim 2, wherein the active ray or radiation is an electron beam or an X ray.

6. The positive resist composition as claimed in claim 2, wherein the active ray or radiation is an excimer laser beam having a wavelength of from 150 to 250 nm.

7. A negative resist composition comprising (F) an alkali-soluble polymer, (G) a crosslinking agent crosslinking with the alkali-soluble polymer (F) by the action of an acid, and (C) a compound having a sulfonimide structure represented by the following formula (I): 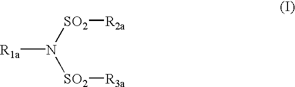
wherein R₁ₐ, R₂ₐ and R₃ₐ, which may be the same or different, each represent an alkyl group which may have a substituent, a cycloalkyl group which may have a substituent, an aryl group which may have a substituent, an aralkyl group which may have a substituent or a heterocyclic group which may have a substituent.

8. The negative resist composition as claimed in claim 7 further comprising (H) a compound which generates an acid by irradiation of an active ray or radiation other than the compound (C).

9. The negative resist composition as claimed in claim 7 further comprising (E) a nitrogen-containing basic compound.

10. The negative resist composition as claimed in claim 7, wherein the alkali-soluble polymer (F) is a polymer containing a repeating unit represented by the following formula (b): 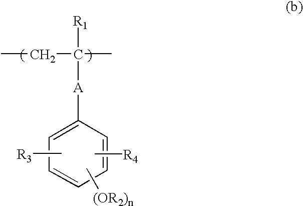
wherein R₁ represents a hydrogen atom, a halogen atom, a cyano group or an alkyl group which may have a substituent; R₂ represents a hydrogen atom, an alkyl group which may have a substituent, a cycloalkyl group which may have a substituent, an aryl group which may have a substituent, an aralkyl group which may have a substituent or an acyl group which may have a substituent; R₃ and R₄, which may be the same or different, each represent a hydrogen atom, a halogen atom, a cyano group, an alkyl group which may have a substituent, a cycloalkyl group which may have a substituent, an alkenyl group which may have a substituent, an aralkyl group which may have a substituent or an aryl group which may have a substituent; A represents a single bond, an alkylene group which may have a substituent, an alkenylene group which may have a substituent, a cycloalkylene group which may have a substituent, an arylene group which may have a substituent, —O—, —SO₂—, —O—CO—R₅—, —CO—O—R₆— or —CO—N(R₇)—R₈—; R₅, R₆ and R₈, which may be the same or different, each represent a single bond, an alkylene group which may have a substituent, an alkenylene group which may have a substituent, a cycloalkylene group which may have a substituent, an arylene group which may have a substituent, or a divalent group formed by combining the above-described alkylene, alkenylene, cycloalkylene or arylene group with at least one member selected from an ether structure, an ester structure, an amide structure, a urethane structure and a ureido structure; R₇ represents a hydrogen atom, an alkyl group which may have a substituent, a cycloalkyl group which may have a substituent, an aralkyl group which may have a substituent or an aryl group which may have a substituent; and n represents an integer of from 1 to 3; or plural R₂'s, or R₂ and R₃ or R₄ may combine with each other to form a ring.

11. The negative resist composition as claimed in claim 7, wherein the alkali-soluble polymer (F) is a polymer containing at least one repeating unit selected from those represented by the following formulae (b-2) and (b-3): 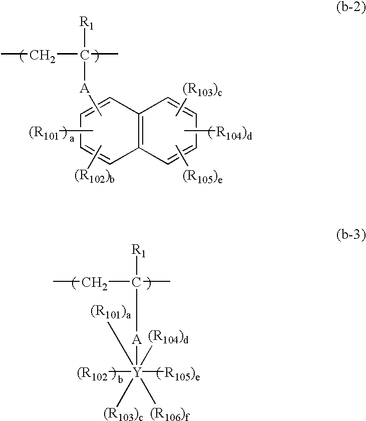
wherein R₁ represents a hydrogen atom, a halogen atom, a cyano group or an alkyl group which may have a substituent; A represents a single bond, an alkylene group which may have a substituent, an alkenylene group which may have a substituent, a cycloalkylene group which may have a substituent, an arylene group which may have a substituent, —O—, —SO₂—, —O—CO—R₅—, —CO—O—R₆— or —CO—N(R₇)—R₈—; R₅, R₆ and R₈, which may be the same or different, each represent a single bond, an alkylene group which may have a substituent, an alkenylene group which may have a substituent, a cycloalkylene group which may have a substituent, an arylene group which may have a substituent, or a divalent group formed by combining the above-described alkylene, alkenylene, cycloalkylene or arylene group with at least one member selected from an ether structure, an ester structure, an amide structure, a urethane structure and a ureido structure; R₇ represents a hydrogen atom, an alkyl group which may have a substituent, a cycloalkyl group which may have a substituent, an aralkyl group which may have a substituent or an aryl group which may have a substituent; R₁₀₁ to R₁₀₆ each independently represent a hydroxy group, a carboxy group, an amino group, an alkyl group which may have a substituent, a cycloalkyl group which may have a substituent, an alkoxy group which may have a substituent, an alkylcarbonyloxy group which may have a substituent, an alkylsulfonyloxy group which may have a substituent, an alkenyl group which may have a substituent, an aryl group which may have a substituent, an aralkyl group which may have a substituent, an N-alkylamino group which may have a substituent or an N-dialkylamino group which may have a substituent; a to f each independently represent an integer of from 0 to 3; and Y represents a condensed polycyclic aromatic structure selected from those shown below.

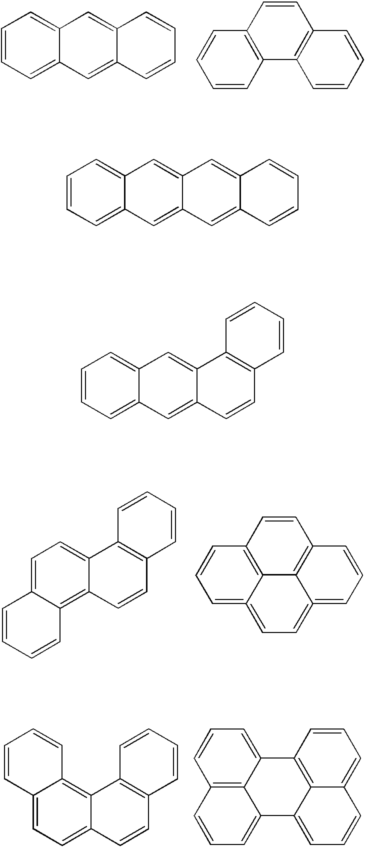

12. The negative resist composition as claimed in claim 7, wherein the active ray or radiation is an excimer laser beam having a wavelength of from 150 to 250 nm, an electron beam or an X ray.

13. The positive resist composition as claimed in claim 2, wherein the polymer (B) which is insoluble or hardly soluble in an aqueous alkali solution but becomes soluble in the aqueous alkali solution by the action of an acid is a resin having a group decomposable with an acid in the main chain or side chain thereof.

14. The positive resist composition as claimed in claim 3, wherein the compound (A) which generates an acid by irradiation of an active ray or radiation other than the compound (C) is a sulfonium salt or iodonium salt represented by the following formula (I), (II) or (III): 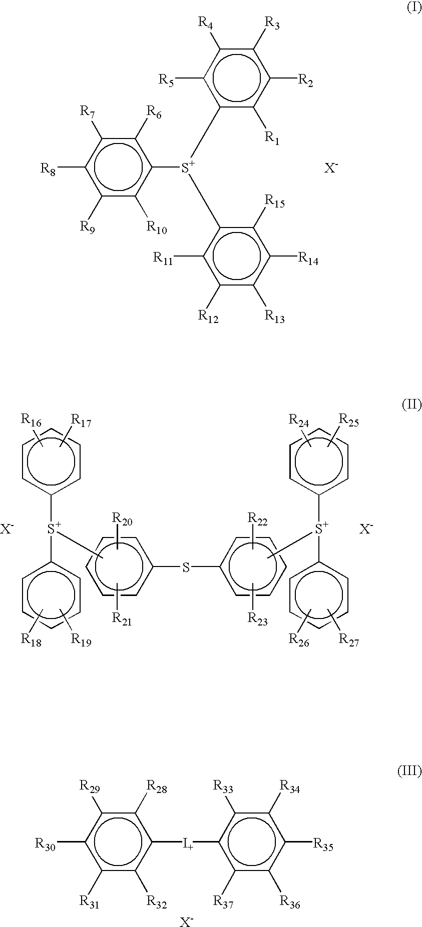
wherein, R₁ to R₃₇ each independently represent a hydrogen atom, an alkyl group, an alkoxy group, a hydroxy group, a halogen atom or —S—R₃₈; R₃₈ represents an alkyl group or an aryl group; and X⁻ represents an anion of an acid.

15. The positive resist composition as claimed in claim 4, wherein the nitrogen-containing basic compound (E) is a compound including a structure represented by the following formula (A), (B), (C), (D) or (E): 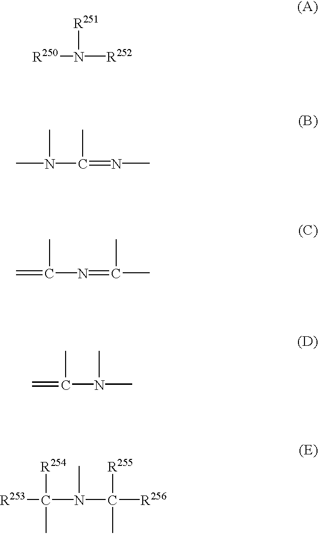
wherein R²⁵⁰, R²⁵¹ and R²⁵², which may be the same or different, each represent a hydrogen atom, an alkyl group having from 1 to 6 carbon atoms, an aminoalkyl group having from 1 to 6 carbon atoms, a hydroxyalkyl group having from 1 to 6 carbon atoms or a substituted or unsubstituted aryl group having from 6 to 20 carbon atoms, or R²⁵¹ and R²⁵² may combine with each other to form a ring; and R²⁵³, R²⁵⁴, R²⁵ and R²⁵⁶, which may be the same or different, each represent an alkyl group having from 1 to 6 carbon atoms.

16. The negative resist composition as claimed in claim 7 further comprising (G) an acid crosslinking agent.

17. The negative resist composition as claimed in claim 16, wherein the acid crosslinking agent is a compound or resin having at least two groups selected from a hydroxymethyl group, an alkoxymethyl group, an acyloxymethyl group and an alkoxymethyl ether group, or an epoxy compound.

18. The negative resist composition as claimed in claim 8, wherein the compound (H) which generates an acid by irradiation of an active ray or radiation other than the compound (C) is an onium salt, an organic halogen compound, an organic metal/organic halogen compound, a photo-acid generator having an o-nitrobenzyl protecting group, a compound generating a sulfonic acid by photolysis, a disulfone compound, a diazoketosulfone compound or a diazosulfone compound.

19. The negative resist composition as claimed in claim 9, wherein the nitrogen-containing basic compound (E) is a compound including a structure represented by the following formula (A), (B), (C), (D) or (E): 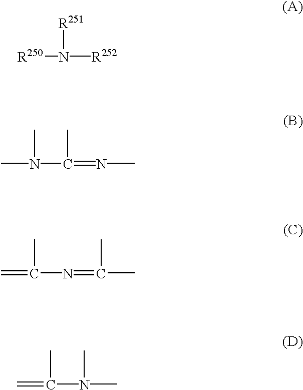
wherein R²⁵⁰, R²⁵¹ and R²⁵², which be the same or different, each represent a hydrogen atom, an alkyl group having from 1 to 6 carbon atoms, an aminoalkyl group having from 1 to 6 carbon atoms, a hydroxyalkyl group having from 1 to 6 carbon atoms or a substituted or unsubstituted aryl group having from 6 to 20 carbon atoms, or R²⁵¹ and R²⁵² may combine with each other to form a ring; and R²⁵³, R²⁵⁴, R²⁵⁵ and R²⁵⁶, which may be the same or different, each represent an alkyl group having from 1 to 6 carbon atoms.
